(19) United States
(12) Patent Application Publication
(10) Pub. No.: US 2012/0006382 A1
(43) Pub. Date: Jan. 12, 2012

(54) THIN AND FLAT SOLAR COLLECTOR-CONCENTRATOR

(75) Inventors: Nadir Dagli, Goleta, CA (US); Ronald Petkie, Thousand Oaks, CA (US)

(73) Assignee: HYPERSOLAR, INC., Santa Barbara, CA (US)

(21) Appl. No.: 13/106,746

(22) Filed: May 12, 2011

(30) Foreign Application Priority Data
Jun. 7, 2010 (US) PCT/US2010/037667

(51) Int. Cl. H01L 31/052; G02B 5/10; H01L 31/18

(52) U.S. Cl. 136/246; 29/890.033; 359/853

(57) ABSTRACT

A photonics-based planar solar concentrator designed for collecting and guiding insolate radiation from one side to solar cells for energy conversion on another side is described. The planar solar concentrator consists of two sections. The top section is a matrix of micro-size wide angle solar concentrators. The bottom section is a planar lightwave circuit, which may be multi-layered. Planar lightwave circuits are used within a relatively thin cross-sectional thickness to guide light from micro-concentrators to output apertures on the opposite surface, such that solar cells can be located directly underneath the concentrator. The planar concentrator can deliver multiple times the normal sunlight intensity to standard silicon solar cells, thereby decreasing the number of cells required in a typical solar module. This planar solar concentrator is designed for use as the top optical layer of a standard flat panel solar module. The concentrator collects light from a relatively wide angle of incidence, and can therefore eliminate the need for active tracking.

### RELATED APPLICATIONS

Pursuant to 35 U.S.C. §366, this U.S. national patent application claims the benefit under 35 U.S.C. §365(a) and 35 U.S.C. §119(a) to the Jun. 7, 2010 filing date of International patent application serial number PCT/US2010/037667 (“the parent PCT application”). Except for paragraph 0001 of the parent PCT application, the contents of the parent PCT application are incorporated herein by reference in its entirety.

### FIELD OF THE INVENTION

The present invention relates generally to the fields of optics, solar energy, and the concentration of insolate energy for the purpose of photovoltaic energy conversion without the use of imaging devices. An optical waveguide circuit system, with a relatively flat form factor, for collecting solar energy, concentrating it, and transmitting it to point of energy conversion is presented. This invention relates generally to solar panels and their improvement, and more particularly, to photonic based waveguides for concentrator solar panels.

### BACKGROUND OF THE INVENTION

The following discussion is provided solely to assist the understanding of the reader, and does not constitute an admission that any of the information discussed or references cited constitute prior art to the present invention.

Solar cells are the most expensive part of solar panels. Current state-of-the-art photovoltaic (PV) cell technology can only convert a fraction of the sunlight received into electricity. This inefficiency requires solar panel manufacturers to use a sizable number of expensive solar cells to deliver a substantial amount of electricity. The high cost of solar panels has prevented solar power from becoming a significant or even primary source of electricity.

Many solutions have been sought to reduce the cost of solar panels. One of these solutions, concentrated photovoltaics (CPV), is to use inexpensive optical elements, such as lenses and mirrors, to concentrate sunlight onto a small surface such that smaller amounts of PV cells can be used. However, since optical elements have non-zero focal length, CPV modules are generally tall and bulky, as opposed to the flat panel design of standard solar modules. Additionally, most CPV systems require active mechanisms to move the entire panel or optical elements to track the position of the sun throughout the day or year. Otherwise, as the sun moves the area of solar concentration moves away from the underlying PV cell, resulting is less or no electricity generation.

Conventional solar modules are made up of silicon solar cells. Due to the inherent temperature limits of silicon solar cells, the amount of solar concentration cannot exceed more than about six for acceptable conversion efficiency performance or before causing possible damage in the case of passive cooling. Therefore, most CPV systems use small amounts of expensive high performance solar cells made from type III-V semiconductor materials that can handle high concentration ratios and high temperatures. While these systems may be economical on small scale installations, III-V compounds are scarce natural materials and cannot be used as the primary material for the world's solar panels. Therefore, silicon solar panels are projected to make up a majority of the PV market in the foreseeable future.

### Wide Angle Solar Collector-Concentrators

One of the major issues in CPV is the tracking required due to seasonal and daily motion of the sun. This issue is typically addressed using active tracking which requires physical motion of the solar elements, mirrors and concentrators to track the movement of the sun. Such elaborate equipment adds complexity and cost. It is possible to do tracking passively. This approach requires collecting elements that collect the sun rays very efficiency over large solid angles. Design of such collection element has been studied by many different authors. The simplest design is shown in FIG. 1. This is effectively a cone design that connects two apertures with a tapered collection element. This element can be designed to provide concentration with a wide angle collection.

The concentration of the collector, C, is given by the ratio of the areas of the input and output apertures when all light is collected. Studies indicate that to efficiently collect over a large solid angle with a concentration of several times, the element has to be relatively long; the length can be more than 10 times the width of the output aperture. Therefore this design becomes impractical even with modest concentration ratios if a commercial solar cell is attached to its output aperture. For example a 6″ rectangular silicon solar cell could need a concentrator longer than 60″ or 5 feet.

### 3D Planar Waveguide Circuit Technology—Optical Microsystems and Photonic Materials

In recent years much progress has been made in regard to forming high quality microstructures and nanostructures using optical quality polymers. The LCD and optical communications industries have contributed to this progress. Processes involving hot embossing, micro-contact printing, reel-to-reel with a master die, casting with molds, photosensitive polymers and grey-scale photolithograhy all have made progress towards the scaling down of polymeric structures with relatively inexpensive and easily implemented processing schemes for high-volume production.

Much work has involved 3D routing of waveguides for optical interconnects between communication routing boards. Heat resistant blends also make it possible for the circuits to endure higher operating temperatures, which is pertinent to operating in sunlight. Research has also uncovered methods for increased optical efficiency and the reduction of intensity losses due to absorption of light in the polymer and scattering due to surface roughness. Hence, the technology of making optical waveguide microstructures from polymers which are heat resistant, optically efficient, and more flexible in terms of processing than glass, is rapidly maturing. This technology has matured to the point where it can offer solutions for the fabrication of optical components for solar cell concentrators, especially at lower concentrations and relatively lower temperatures.

### SUMMARY OF THE INVENTION

The present invention provides a highly advantageous device for concentrating incident light, and is particularly applicable to photovoltaic systems, and in particular to increasing the performance of conventional photovoltaic cells and panels. Using these devices enables the light incident on photovoltaic cells to be increased, thereby reducing the photovoltaic cell area needed for a particular level of power generation. Furthermore, the light concentration and resulting decreased photovoltaic cell area can be accomplished without requiring a tracking mechanism to keep the cells oriented to the sun. The devices are useful for essentially any flat panel photovoltaic system, including silicon-based panels and Group III-V panels. Thus, the present light concentrators provide more efficient use of photovoltaic materials without the complexity of producing hybrid cells.

The invention provides a number of design variants. Particularly desirable are designs which incorporate light concentration through the use of collector-concentrator structures, as well as concentration within the plane of a planar waveguide circuit (PWC). In such designs, it can also be advantageous to incorporate diffusers to spread the light more evenly over the surface of the solar cell. A number of design options are described below.

Thus, a first aspect of the invention concerns a flat solar concentrator and photovoltaic device, which includes a flat array of wide angle solar concentrators mounted on and optically coupled with a waveguide layer, and a flat photovoltaic panel, where the flat array and the flat photovoltaic panel are optically connected such that light concentrated by the solar concentrator is directed onto the photovoltaic panel thereby producing electricity.

In particular embodiments, the flat array is mounted on top of the photovoltaic panel; the photovoltaic panel is mounted on an edge of the flat array.

In advantageous embodiments, the waveguide layer includes a first set of mirror surfaces (e.g., dielectric or metal-coated mirror surfaces) which redirect light exiting the concentrators substantially in the plane of the waveguide layer, and optionally the waveguide layer includes a second set of mirror surfaces which redirect light from the first set of mirror surfaces to a direction substantially perpendicular to the plane of the flat array; the concentrators are optically coupled to the waveguide layer through waveguide bends.

In certain embodiments, the flat array concentrates insolate light by a factor of at least 1.5, 2, 3, 4, 5, 6, 7, or 8.

In particular embodiments, the concentrators are hexagonal, square, near square (e.g., with the ratio of length to width of the inlet aperture no more than 4:1, 3:1, 2.5:1, 2:1, 1.5:1, or 1.2:1), or trough concentrators; concentrator of a type as just specified are in a close-packed array; the PWC has a single layer having a waveguide which includes at least one S-bend and at least one junction; the PWC includes at least one layer (e.g., 1, 2, 3, 4, or more layers), where each of those layers includes a waveguide which includes at least one S-bend and at least one junction; the at least one PWC layer includes an in-plane concentrator (e.g., a taper structure); the waveguide has lateral air cladding and/or vertical air cladding (i.e., air gaps between layers of the PWC); the PWC includes a plurality of layers (e.g., 2, 3, 4, 5, or more layers) separated by air gap defined by spacers between said layers (preferably with spacers located in non-light conducting areas of the layers).

Also in certain embodiments, a waveguide is optically coupled to a spreader (e.g., an expanding taper) and/or a diffuser (e.g., an inverted cone) which spreads light from the waveguide over the surface of a photovoltaic cell in the photovoltaic panel.

In further embodiments the device includes a wavelength separator which separates light of different ranges of the light spectrum, e.g., within or adjacent to a waveguide); the device includes an IR separator and/or a UV separator; the separator is or includes a thin film interference filter (e.g., located at or near the narrow end of an in-plane concentrator); the device includes a wavelength separator (e.g., as part of or adjacent to one or more waveguides) which preferentially separates and removes light in a particular portion of the light spectrum (e.g., IR and/or UV light) from light which is conducted to the photovoltaic panel, for example a thin film interference filter.

A related aspect concerns a flat solar concentrator which includes a flat array of wide angle solar concentrators mounted on and optically coupled with a waveguide layer, where the waveguide layer is configured such that light exiting from the concentrators is redirected within the waveguide layer to a direction parallel to the plane of waveguide layer.

In particular embodiments, the flat solar concentrator is as described for the preceding aspect or an embodiment thereof or otherwise described herein for the present invention.

Another related aspect concerns a method for making a flat solar concentrator, involving optically coupling a flat array of wide angle solar micro-concentrators having an incident light area with a waveguide layer, where the waveguide layer accepts output light from the concentrators and outputs light into a light output area smaller than the incident light area.

In particular embodiments, the light output area is from about 0.7 to 0.05, 0.5 to 0.1, 0.5 to 0.15, or 0.3 to 0.15 times the incident light area; the waveguide layer includes a plurality of sub-layers, e.g., 2 to 5, 3 to 8, 4 to 10, 7 to 15, 10 to 20, or at least 4, 6, 8, 10, 15, or 20 layers.

In certain embodiments, the flat array has a thickness of about 0.1 to 5.0, 0.1 to 3.0, 0.1 to 3.0, 0.1 to 2.5, 0.1 to 2.0, 0.1 to 1.5, 0.1 to 1.0, 0.1 to 0.7, 0.2 to 5.0, 0.2 to 4.0, 0.2 to 3, 0.2 to 2.0, 0.2 to 1.0, 0.2 to 1.0, 0.2 to 0.7, 0.3 to 5.0, 0.3 to 4.0, 0.3 to 3.0, 0.3 to 2.0, 0.3 to 1.0, 0.3 to 0.7, 0.3 to 0.6 cm, 0.5 to 5.0, 0.5 to 4.0, 0.5 to 3.0, 0.5 to 2.0, 0.5 to 1.5, 1.0 to 5.0, 1.0 to 4.0, 1.0 to 3.0, 1.0 to 2.0, 2.0. to 5.0, or 2.0 to 4.0 cm; the waveguide layer has a thickness of less than about 5.0, 4.0, 3.0, 2.0, 1.0, 0.9, 0.8, 0.7, 0.6, 0.5, 0.4, 0.3, 0.2, or 0.1 cm; the thickness of the flat solar concentrator is about 0.2 to 5.0, 0.2 to 4.0, 0.2 to 3.0, 0.2 to 2.0, 0.2 to 1.5, 0.2 to 1.2, 0.2 to 1.0, 0.3 to 5.0, 0.3 to 4.0, 0.3 to 3.0, 0.3 to 2.0, 0.3 to 1.5, 0.3 to 1.2, 0.3 to 1.0, 0.3 to 0.7, 0.5 to 5.0, 0.5 to 4.0, 0.5 to 3.0, 0.5 to 2.0, 1.0 to 5.0, 1.0 to 4.0, 1.0 to 3.0 cm; the solar concentrator includes a flat array and a waveguide layer where the respective thicknesses of the flat array and the waveguide layer are any discrete combination of the flat array thickness and waveguide layer thickness specified for previous embodiments.

Also in certain embodiments, the flat array is bonded with the waveguide layer.

In particular embodiments, the resulting flat solar concentrator is as described for the preceding aspect or an embodiment thereof or otherwise described herein for the present invention.

Still another related aspect concerns a method for reducing the photovoltaic panel area required in a photovoltaic power system of a specified electrical power generation capacity, by including in the system a flat solar concentrator as specified in any preceding aspect, optically coupled with at least one photovoltaic panel in the system.

Additional embodiments will be apparent from the Detailed Description and from the claims.

### BRIEF DESCRIPTION OF THE DRAWINGS

FIG. 1 shows a side view of a wide angle solar concentrator, where the input aperture, of radius a₁ (or width), collects insolate radiation and directs it towards an output aperture of radius a₂ (or width) at the bottom, where it is concentrated in the process of being collected.

FIG. 2 shows two space-filling micro-concentrators geometries for collecting sunlight in relatively flat Collector-Concentrator array. A single micro-concentrator is generally a cone-like vertical structure and directs the light from the top insolated surface towards an aperture at the base. The inner surface of the cone-like structure may either be a mirror-like and/or the inside of the structure can be filled with a graded index material.

FIG. 3 shows a matrix of square-shaped micro-concentrators comprising the Collector-Concentrator.

FIG. 4 shows an example of a cross-section through a micro-concentrator plane comprised of conical micro-concentrators, with the cross-section through the center of micro-concentrators. An optional graded refractive index (GRIN) fills the volume of micro-concentrator. Alternatively, a metalized surface can also provide a mirrored surface for internal reflection within the micro-concentrator. The index of refraction is higher in direct correspondence to the darker gray color.

FIG. 5 is a cross-sectional conceptual diagram illustrating the path of sunlight in the invention: collection-concentration, and redirection of sunlight.

FIG. 6 shows a one-to-one mapping of micro-concentrator output aperture area to the output pixel area.

FIG. 7 schematically shows a micro-concentrator and waveguide combination providing 4× light concentration. The waveguides are the same size in cross-section as the bottom apertures in the micro-concentrators and the final output aperture, or ‘pixel’, at the bottom of the PWC. The light exiting from the output aperture is preferably directed at a solar cell. If adjacent rows in the Collector-Concentrator progressing in the y direction are staggered horizontally by width of a ‘pixel’ in a consecutive manner as shown above, then for illumination of the ‘pixels’, adjacent rows can be paired to correspond to horizontally adjacent ‘pixels’ in a given row. For 4× concentration, which is given by the ratio of the top to the bottom area of the micro-concentrators, one row of pixels is illuminated by two rows of the Collector-Concentrator. Since this can be repeated for each side of the ‘pixel’ rows, then two rows of ‘pixels’ are illuminated by a pair of two rows on either side of the Collector-Concentrator in a given layer of the planar waveguide circuit. If the output area is divided into M×N pixels, then M/2 layers of waveguides are needed.

FIG. 8 is a cross-sectional view of planar waveguide circuits at different layers is shown. Waveguides are placed on transparent polymer or glass sheets. Nested sets of light paths are illustrated through the use 45° micro-mirrors for directing light into a PWC layer for processing, and then to the final output pixels area. There is always one mirror directly under the micro-concentrator collector (m-c) and another one directly above an output pixel area. For the given mapping in FIG. 7, for every step in the y direction, a new layer is needed with additional waveguide length to accommodate the increasing distance from the output pixels. For M layers, then are M unique waveguide patterns.

FIG. 9 shows a staggered configuration of micro-concentrators providing an increased concentration ratio. The same principle applies for higher concentration ratios, where the additional micro-concentrators are staggered to accommodate a higher density of pixels horizontally to increase the light concentration further at the output area.

FIG. 10 is a plan view of a conceptual block diagram of Planar Waveguide Circuit (PWC) optical components in a single layer illustrating the optical function of components within the invention. The light is taken from the light source to the light output sections with 45 degree micro-mirrors. Components reduce the total number of the PWC layers by efficiently processing light prior to the output area. An arbitrary concentration of light can be obtained. Combining the output of rows of micro-concentrators into a single waveguide allows both IR separation and flexibility in distribution. Several such arrangements can be combined in the same layer reducing the number of layers.

FIG. 11 shows another plan view of a PWC unit on one layer for concentration of light with a one-to-one area correspondence between micro-concentrator output apertures and output pixels with an overall concentration factor of 9. Waveguides are used to geometrically remap light from the micro-concentrators to the output pixel area, which generally have different lateral dimensions. Additional layers can provide mapping from vertically adjacent rows in the Collector-Concentrator matrix to the output pixel matrix.

FIG. 12 shows an example of an array of planar waveguide circuits that transfer light from Collector-Concentrator of source area, A_{c}, to an output area for absorption by photovoltaic devices, Aₚ. A functional block diagram of a single-level in a 3D PWC of the invention shows a possible serial waveguide processing of sunlight in correspondence to the physical layout of the passive optical components in the overall network of light concentration. The micro-collector concentrators are all on the same level at the top surface, while additional layers can reside either above or below the level shown. The bottom level consists of output apertures.

FIG. 13 is another Example showing a sketch of a 4:1 Concentrator Using 2 Layers—2D View. This design needs 2 DIFFERENT PWC Layer Designs because of m-c input area is not the same as output area. Concentration is done in the micro-concentrator. Different PWC Layer Designs are needed when the Collector Input Area is greater than the Output Pixel Area.

FIG. 14 schematically shows a repeatable Single Layer Design: If micro-concentrators (m-c) area is the same as the output pixel area, then concentration can be done using the waveguide combiner (in the x-direction). The design is an 8 layer, 4:1 concentrator. Light is collected by 16 horizontal micro-concentrators (m-c) then delivered to 4 output pixels. Each texture represents a different layer. No components with the same texture can touch to avoid spatial conflicts. In order to minimize the number of layers, a spatial mapping layout algorithm for equal areas is as follows. Start the PWC from the bottom edge of Collector Area to bottom edge of Output Area. REPEAT vertically, introduce new layers until all rows of the Output Area is covered. Since this step is a vertical translation by one output pixel unit, then the same optical components can be repeated by one layout mask. SHIFT horizontally. IF Any Layout Constraint is Violated, THEN introduce new layer and REPEAT from Step 2, UNTIL no more Layout Constrains are violated. REPEAT from Step 2 using existing layers, until total desired area is covered.

FIG. 15 shows Micro-Concentrators Coupled into a Multi-Layered Photonics Waveguide Circuit. A perspective view of the overall design in the invention that embodies the concept of collecting, concentrating, and re-directing insolate radiation from an input aperture to an output aperture by use of a micro-system of optical components—a Planar Waveguide Circuit (PWC).

FIG. 16 shows a cross-sectional perspective view of the ensemble of Collector-Concentrator with multiple layers of planar waveguides and 45° micro-mirrors to redirect light from vertical to horizontal and back to vertical paths.

FIG. 17 illustrates a waveguide coupler as a Combiner-Splitter for re-concentrating the light in four waveguides to output in three waveguides.

FIG. 18 shows a Collector-Concentrator and PWC with a four-to-three waveguide Combiner-Splitter component on one layer. A waveguide coupler is representative of the center section as a possible manufactured part using polymers.

FIG. 19 schematically shows a waveguide coupler for separating infrared wavelength.

FIG. 20 illustrates an example of an injection molding process to fabricate the Collector-Concentrator.

FIG. 21 illustrates an example of a hot embossing process to fabricate the Collector-Concentrator.

FIG. 22 illustrates hot embossing of polymer sheets, where the mold and Polymer sheet are heated (a), mold pressed against sheet (b), and mold removed leaving an impression as in (c).

FIG. 23 illustrates reel-to-reel hot embossing to fabricate a Collector-Concentrator.

FIG. 24 illustrates a PDMS casting process for the fabrication of planar waveguides.

FIG. 25 illustrates the fabrication of via holes through the substrate.

FIG. 26 shows an encapsulation and integration process of the layers in the invention between two layers of glass.

FIG. 27 schematically illustrates an assembly of a trough-type micro-collector concentrator with a PWC layer.

FIG. 28 illustrates a conical micro-collector concentrator.

FIG. 29 illustrates a trough-type micro-collector concentrator.

FIG. 30 illustrates an array of trough-type collector concentrators.

FIG. 31 shows cross-sectional and plan views of a single PWC layer with beveled edges forming micro-mirrors.

FIG. 32 schematically illustrates an assembly of a micro-collector array with a PWC stack and output pixel array.

FIG. 33 is an expanded schematic view showing optical coupling of a micro-collector concentrator with a PWC using an optical adhesive.

FIG. 34 shows an assembly of trough-type micro-collector concentrators with mirror image PWC stack assemblies.

FIG. 35 shows an alternative PWC micro-mirror design in which the micro-mirror bevels are internal to the PWC sheet instead of at the extreme edges.

FIG. 36 shows alternative waveguide contours.

FIG. 37 is a perspective view illustrating a possible interconnection between two conical micro-collector concentrators.

FIG. 38 is a perspective view illustrating an array of conical trough-type micro-collector concentrators forming a single PWC layer as seen from the side.

FIG. 39 is a bottom view illustrating an array of conical trough-type micro-collector concentrators forming a single PWC layer.

FIG. 40 shows cross-sectional and plan views of a single PWC layer with beveled edges forming micro-mirrors.

FIG. 41 schematically illustrates an assembly of a micro-collector array with two stacked PWC layers.

FIG. 42 is an expanded schematic side view showing optical coupling of a micro-collector concentrator with a PWC using an optical spacer between PWC layers.

FIG. 43 shows a plan view of the bottom of an assembly of trough-type micro-collector concentrators with PWC stack assemblies.

FIG. 44 is a schematic side view of a design in which light collected with an array of micro-collectors is spread over a solar cell using inverted cones.

FIG. 45 shows three schematic side views showing different optical coupling devices coupling light from micro-collectors into a PWC layer.

FIG. 46 is a schematic top view of an exemplary PWC layer for a single layer device. For clarity only a subset of the elements are shown.

FIG. 47 schematically illustrates three different implementations of basic units that can be used for power combining and concentration. The difference in gray scale delineates different elements.

FIG. 48 schematically illustrates an exemplary optical structure for power combining using multiple waveguides.

FIG. 49 is a 2D schematic showing power splitting into several waveguides before illuminating the solar cell.

FIG. 50 is a perspective 3D rendering of an example of a structure for power splitting into several waveguides before illuminating the solar cell. Only one diffuser cone is shown for clarity

FIG. 51 schematically shows a PWC plane cut out of a solid sheet of material. White areas are the cuts and the PWC is inside the cuts. PWC is attached to the rest of the plane which is not optically active at tie points. The difference in gray scale is used to delineate elements.

FIG. 52 illustrates a desired reflection spectrum of the wavelength selective surface.

FIG. 53 is a side schematic view of the PWC showing how the wavelength selective surface made out of a thin film interference filter is attached.

FIG. 54 is a top schematic of a section of a PWC showing an example of a position of attachment of the wavelength selective surface made out of a thin film interference filter. The difference in gray scale is used to delineate elements.

FIG. 55 is a schematic side view illustrating in exaggerated form the stack construction of a thin film interference filter.

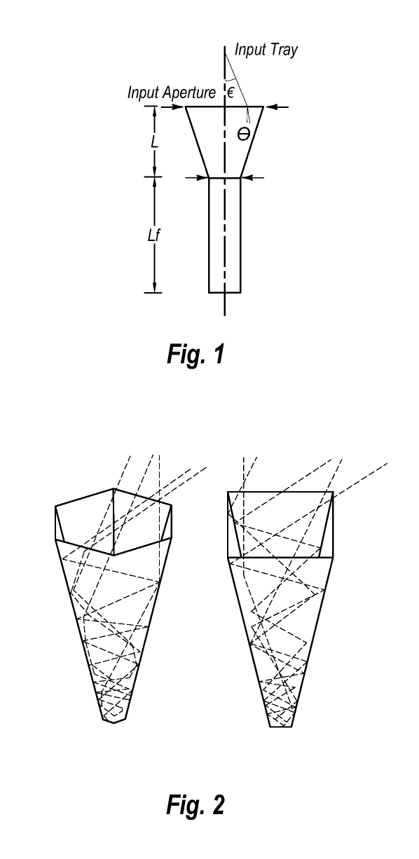

### DETAILED DESCRIPTION OF THE PREFERRED EMBODIMENTS

The invention presented here concerns a thin and flat solar concentrator for direct placement on top of solar cells, obtained by coupling the principles of optical solar concentrators and photonics waveguide circuitry and techniques. The design of this present invention can be configured as a low value concentrator (e.g., for placement on top of silicon solar cells), or as a high value concentrator (e.g., for placement on top of high performance III-V solar cells). An advantageous embodiment of the solar concentrator in this invention is a thin optical layer that can replace the glass layer in standard flat solar panel designs. Certain advantageous embodiments utilize in-plane concentrators as part of the waveguide circuit, in addition to the initial collector-concentrators which are typically oriented with the optical axis perpendicular to the plane of the solar cell surface.

Thus the invention includes a photonics-based planar solar concentrator designed for collecting and guiding insolate radiation from one side of the concentrator, to solar cells for energy conversion on another side. In general, the planar solar concentrator includes two sections. The top section has a matrix (usually a close-packed matrix) of micro-size wide-angle solar concentrators for the collection of input light. The use of micro-size wide-angle solar concentrators can, in a many cases, eliminate the need for tracking mechanisms and achieves a thin profile. The output of each micro-concentrator is coupled to a photonics waveguide, where the light is directed to an output area on the opposing side (or to an edge) through the use of a network of waveguides (often a multi-layered network) and micro-mirrors (usually 45 degree micro-mirrors) and/or curved waveguides. The effective geometric concentration ratio of the concentrator of this invention is calculated as: (concentration ratio)=(aggregate collection area of the micro-concentrators)/(aggregate output area of the waveguides).

For the flat solar concentrator invention presented here, the Collector-Concentrator layer serves to collect from a total specified insolated area, A_{c}, of an arbitrary boundary, and the passive planar waveguide circuit distributes the concentrated light energy over a total output area, Aₒ , of an arbitrary boundary. A_{c/}Aₒ is the effective concentration ratio of the concentrator in this invention modulated by a waveguide circuit factor, which is dependent on how the light is directed and combined, passively and linearly, in an additive manner. Any device utilizing the concentrated light can be attached to the output area, preferably a photovoltaic solar cell.

The need for tracking mechanisms and equipment in conventional solar concentrators is solved or at least significantly reduced by this invention by the matrix of micro-concentrators. Each micro-concentrator has small input and output apertures, and as a result can be very short, e.g., several millimeters, while having a very wide collection angle. The light at the output apertures from the plane of micro-concentrators is coupled into multi-mode optical waveguides using reflectors, usually 45° reflectors, or curved waveguides. Therefore, the micro-concentrators can be used as passive (static) tracking elements that couple the sunlight into planar optical waveguide circuits.

In addition to collection and concentration using the micro-concentrator waveguide structure, sunlight can optionally be further spectrally processed (e.g., in the waveguide layer) and diverted onto any type of solar cell, e.g. the redirection of specific bands of wavelengths for particular solar cells. The coupling of the collected light onto the solar cell can be done by again using reflectors (e.g., using 45° turning mirrors) or curved waveguides at the final output aperture below the plane of the waveguides. These mirrors or curved waveguides direct the insolate concentrated radiation in the waveguide through apertures in the final output plane, providing a plane of concentrated light, e.g., for solar cells in a module.

Advantageous embodiments of this invention include the following common characteristics:
1. A flat and thin solar concentrator that conveniently accommodates the current solar cell module form factor containing individual solar cells wafers or area(s) of active photovoltaic conversion.
2. The total area of the input apertures, insolated on the top side of the concentrator, is larger (usually multiple times larger) than the area of the output apertures at the bottom of the concentrator.
3. A space-filling matrix of optical micro-concentrators constructed in a plane, known as a Collector-Concentrator, which serves to collect insolate light at wide angles at the top surface and guide the light to the bottom surface through multiple input and output apertures, respectively, where the input aperture has an area larger than the output aperture. The wide angular acceptance of solar radiation by the individual micro-concentrators makes passive tracking possible for the entire concentrator.
4. A planar waveguide circuit, often multi-layered, where the output of each micro-concentrator above is coupled to an aperture in a waveguide in a planar waveguide circuit (“PWC”), and the concentrated light energy, in the process of passing through the PWC, may be directed through 90 degrees turns with 45 degree micro-mirror reflectors or curved waveguides so as to be directed both vertically and horizontally through PWC, and finally transferred to an output aperture at the bottom side (or alternatively at a lateral side).
5. Optionally, infrared, near infrared, and/or ultraviolet radiation, or other wavelength bands of the solar radiation spectrum, is separated from other light in the waveguide circuit through a wavelength separator, e.g., using a thin film interference filter. For example, infrared light can be separated and removed, where such infrared light would otherwise increase the temperature of the solar cell thereby reducing conversion efficiency. That is, the incorporation of a wavelength separator for either passive thermal management, or for more efficient use of the solar spectrum, passive wavelength management, where portions of the solar spectrum that can be directed towards a specific solar cell material to maximize light absorption, and therefore conversion efficiency.
6. Preferably applying an optical microsystem-based fabrication technology, including photonic materials, for the purpose of concentrating insolate energy cost effectively through the fabrication of optical polymers or glasses of sufficiently low optical density; and eventually apply high-volume production techniques for further cost reduction.
7. The planar area of light collection of the Collector-Concentrator is highly preferably maximized through conforming to a space-filling geometry, such as hexagonal or rectangular (e.g., square) lattices.
8. To optionally provide a spherical (or other) superstructures over each micro-concentrator in accordance with collection performance for capturing more insolate light from the environment.
9. An optionally geographic-specific custom designed product with consideration to average annual diffuse and direct insolation, operating temperature, and solar light concentration.

### A. Collector-Concentrator—Matrix of Micro-Concentrators

As indicated in the discussion above and in the drawings, micro-concentrators may be shaped and configured in various ways. Thus, micro-concentrators may, for example, be circular, square, rectangular, hexagonal, or other shape in cross-section perpendicular to a line connecting the centers of the input and output apertures of the micro-concentrators. In any case, the shapes, dimensions and materials are selected such that light which enters the top of the micro-concentrator over a capture angle is directed by reflection and/or refraction down the concentrator and out through an output aperture. In this context, the input and output apertures refer to the light entry and exit areas for the concentrator, even if the interior of the concentrator is filled.

As indicated, the micro-concentrators (also referred to as collector-concentrators) can be configured in various ways, which can include different relative areas of inlet and output apertures. Those relative areas determine the initial light concentration. Commonly, the micro-concentrators provide about a 2× concentration factor, although micro-concentrators with many other concentration factors (either higher or lower) may be utilized.

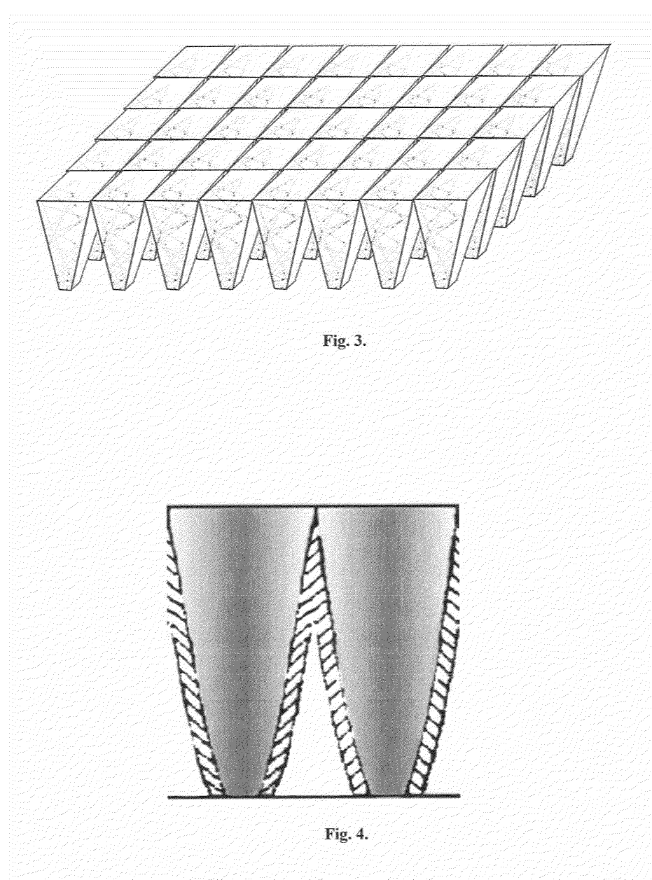

In order to efficiently use space, it is beneficial to select a micro-concentrator shape which allows close packing of the concentrators in a flat array. Thus, for example, square and hexagonal micro-concentrators can advantageously be used to form the array or matrix. Such micro-concentrators are schematically illustrated in FIG. 2. If square (or other rectangular shape) concentrators are used, the array can be laid out in many different ways, and in particular can be laid out with offsets between concentrators in different rows. An array of square micro-concentrators without offset between rows is illustrated in FIG. 3. In contrast, hexagonal micro-concentrators in a flat hexagonal close packed array will naturally have an offset of ½ the input aperture.

An advantage of using micro-concentrators is that the flat array can form a relatively thin layer or sheet. The depth of the layer will, of course, depend on the design and size of the micro-concentrators, but commonly will be less than 1 cm, and preferably less than 0.7, 0.5, or even 0.3 cm.

As also discussed elsewhere, the micro-concentrators may be empty (e.g., air-filled) or may be filled with a solid (e.g., a transparent plastic such as PMMA). Further, the micro-concentrator may be designed such that a reflective layer is deposited on the wall of the micro-concentrator and/or light may be maintained and directed within and through the micro-concentrator using refraction/reflection effects due to changes in refractive index of materials through which the light is passing within the concentrator. An example of micro-concentrators which utilize differences in refractive index is shown in FIG. 4.

### B. Planar Waveguide Circuits or Photonic Waveguide Circuits (PWC) and Design Examples

In addition to the array of micro-concentrators, the present devices advantageously utilize a flat or planar waveguide (which frequently will have multiple layers) which is usually mounted to the underside of the collector array, e.g., using a clear bonding layer. Utilization of such a planar waveguide allows the overall device to be relatively thin, e.g., preferably less than 5, 4, 3, 2, 1.5, 1.2, 1.0, 0.9, 0.8, 0.7 cm or even thinner.

The waveguide is constructed such that light entering the waveguide from a concentrator is diverted (e.g., using a mirror surface or curved waveguide) so that it travels essentially in the plane of waveguide. In many cases, a second mirror surface or curved waveguide is used which then diverts the light from traveling the plane of waveguide to traveling substantially perpendicular to the plane of the waveguide, exiting the waveguide at a location directly below the second mirror or below the exit aperture of the curved waveguide or extension thereto. Highly preferably, the waveguide circuits have negligible reflection, diffraction, absorption, and scattering in the waveguide layers.

Some of the possibilities for waveguide layout and overall design are described below and in the drawings.

### Embodiment 1

### Waveguide Circuit and Light Collection Device with In Plane Concentration and/or Waveguide Junctions

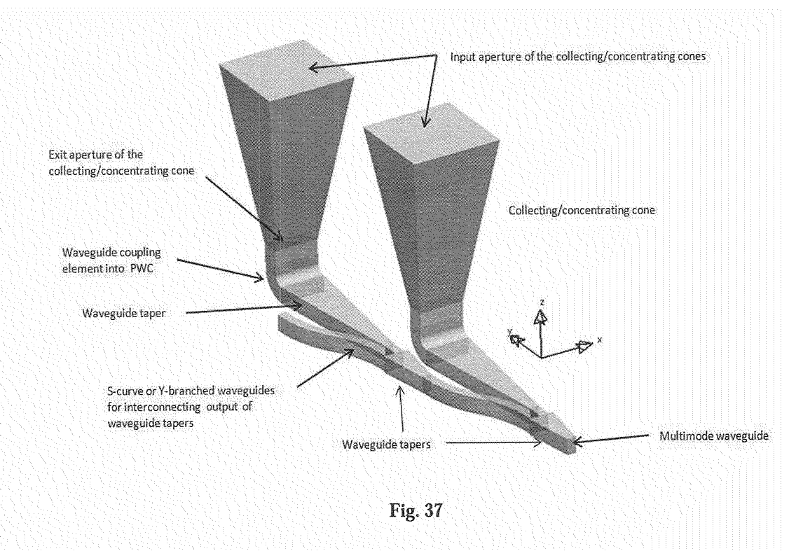

Particularly advantageous designs for collector and waveguide is illustrated in FIGS. 37-43. In these types of waveguide designs, the collected light is channeled to the lower aperture of the collector-concentrator and optically coupled to a PWC. Rather than merely being an optically clear planar waveguide, this design uses a planar set of light channels, which are relatively narrow waveguides. The PWC can include multiple types of elements, for example, in-plane concentrators or tapers, light channels, light junctions or combiners, light splitters, diffusers, and wavelength separators (e.g., IR separators).

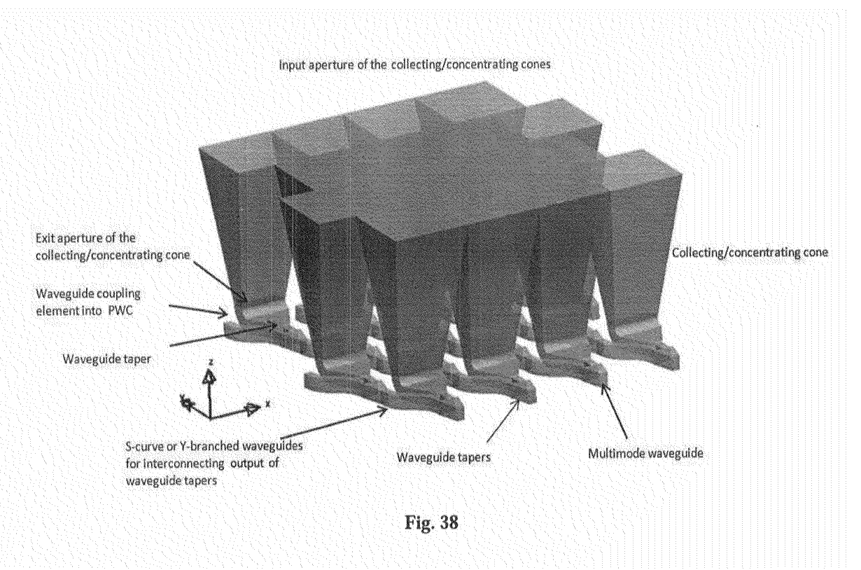

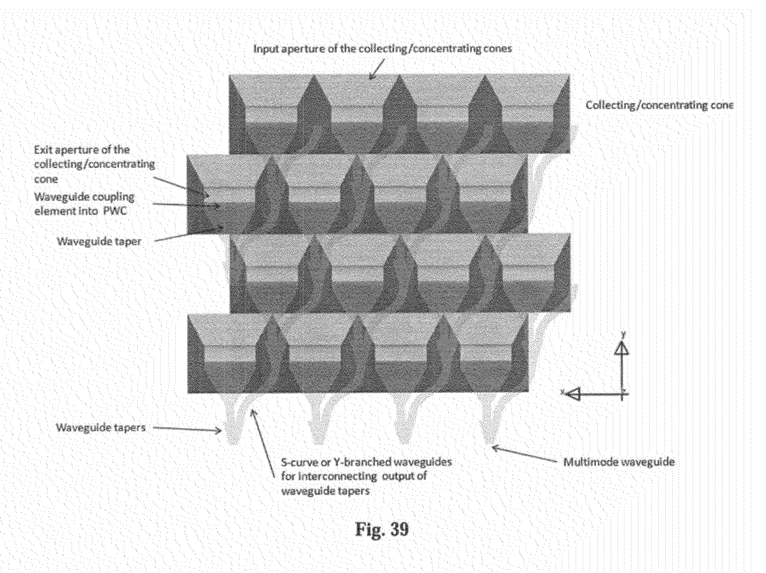

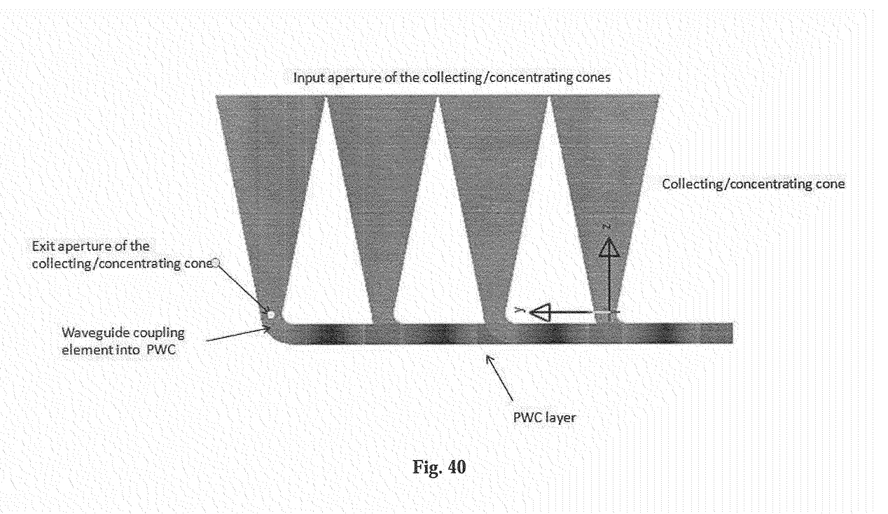

FIG. 37 shows an example of one type of interconnection between two cone collectors, with elements for coupling light from the collectors into waveguides in the PWC, with in-plane concentrators (shown as waveguide tapers), S-bends or Scurves, and Y-combiners. FIG. 38 shows a perspective view of one way an array of cone collectors and additional optical elements can be arranged to collect and deliver the light into a set of relatively narrow waveguides. FIG. 39 shows substantially the same arrangement as a bottom plan view, while FIG. 40 shows a side view.

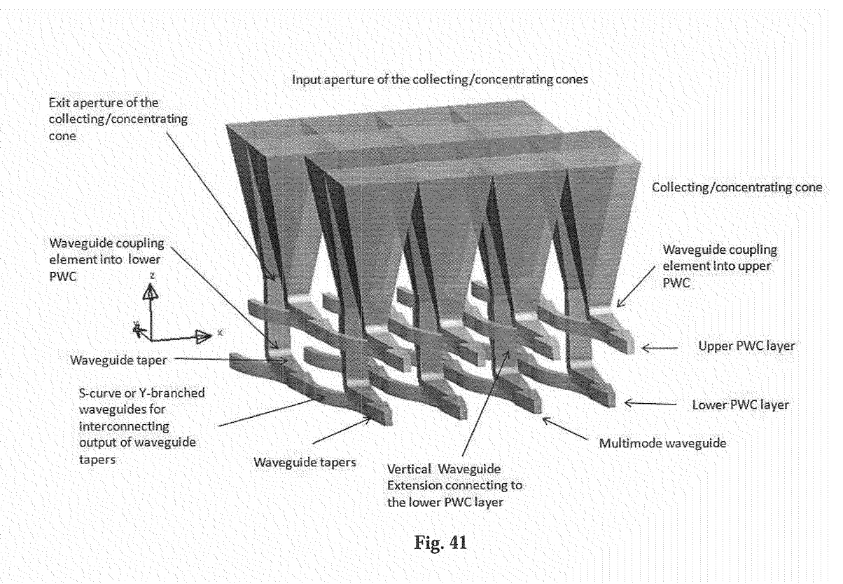

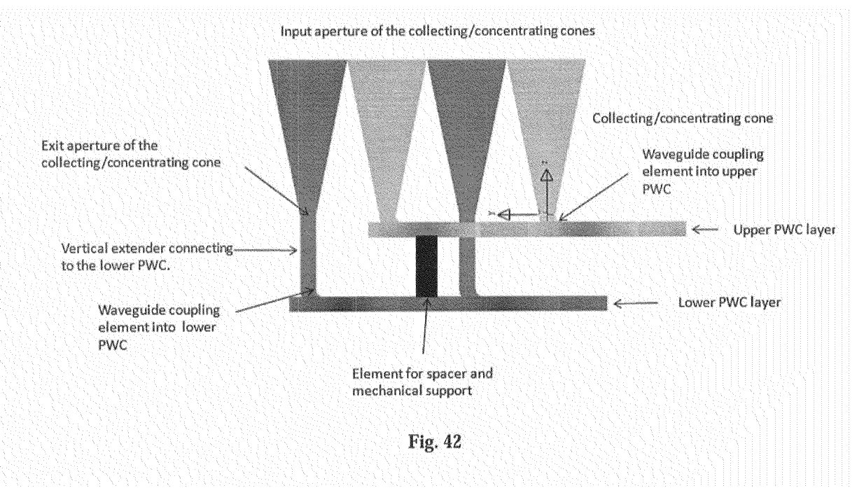

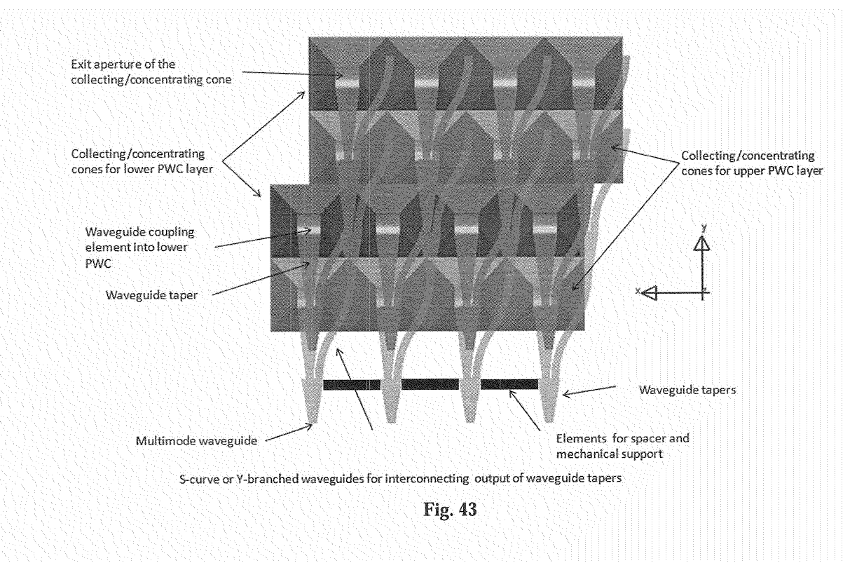

An example of a two-layer PWC for a collector-concentrator array is illustrated in FIG. 41. As shown, light from the collector-concentrators is coupled into waveguides in two different layers. Such multi-layer approach can be useful, for example, where geometric constraints make it difficult or impossible to connect all collector-concentrator outputs in a single layer. The multi-layer approach (again illustrated with two layers) is shown clearly in side view in FIG. 42. Here, the lower layer is reached by using vertical extenders from the exit aperture of the collector-concentrators, and the layers of the PWC are stabilized with spacers, highly preferably located in non-light conducting portions of the PWC layers. A layout and connections to the waveguides for a two-layer PWC is illustrated in plan view in FIG. 43.

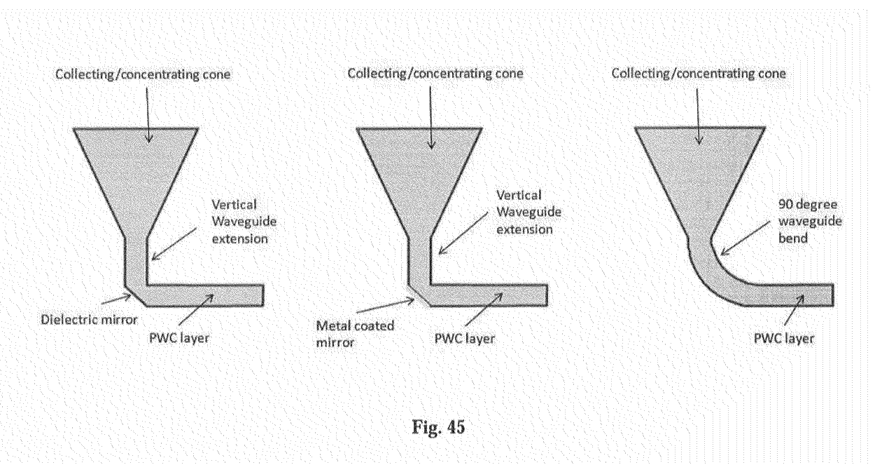

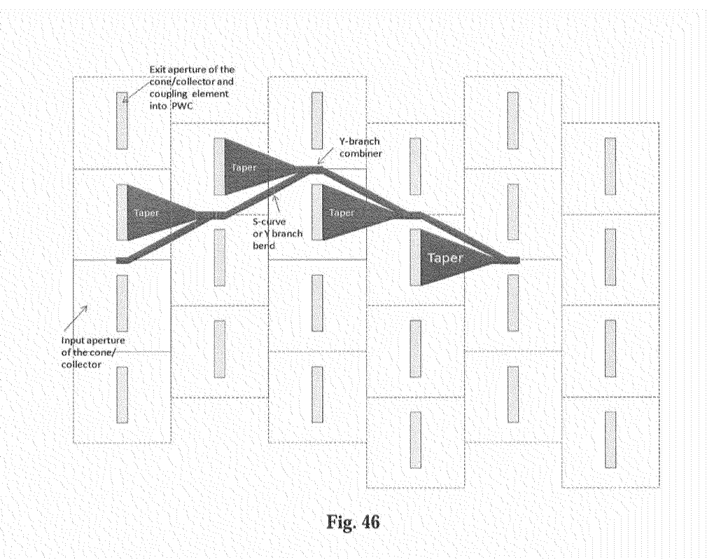

In the illustrated examples, the light is collected in an array of collector-concentrators (e.g., an array in which the collector-concentrators have square or near square rectangular upper apertures which narrow to a rectangular lower aperture. Three different types of coupling elements between the collector-concentrator and the PWC are shown in FIG. 45.

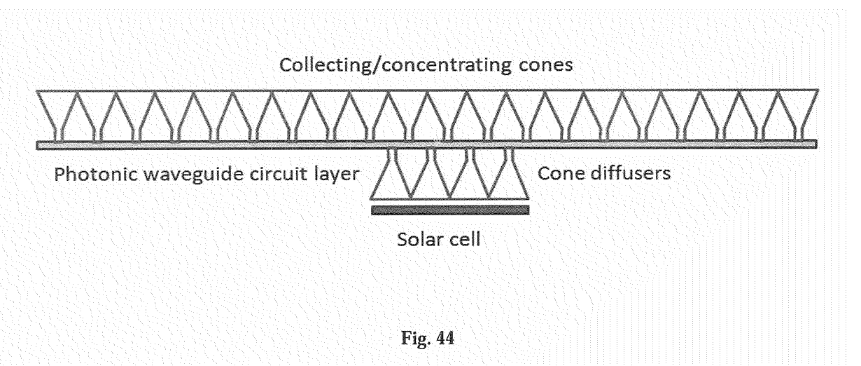

Another simplified schematic of this type of design is shown in FIG. 44. It includes collecting/concentrating cones (i.e., collector-concentrators) that collect the incoming sunlight and traps it in a short vertical waveguide. The light in this waveguide is diverted into a planar photonic waveguide circuit (PWC). Light is further manipulated in this PWC, which can have several stacked PWC planes. This manipulation involves combining and concentrating the light collected by the cones in multi-moded optical waveguides. Spectral separation of the solar radiation can also be done. Furthermore these waveguides transport the collected light or spectrally separated light to the top of an existing commercial solar cell or cells. Finally the light from the PWC is diverted into diffusing cones which are used to uniformly illuminate the underlying solar cell with the concentrated and optionally spectrally separated solar radiation.

The PWC is an important part of this invention. As indicated above, the solar radiation captured by the collecting/concentrating cones is coupled to the PWC, e.g., thorough 45° dielectric mirrors, 45° metal coated mirrors, or 90° waveguide bends. FIG. 45 shows the cross sectional profile of these various coupling approaches. Thus, as shown in FIG. 45, the first coupling technique shown utilizes a 45° dielectric mirror (using TIR) to divert light passing down through the vertical waveguide extension into the PWC layer. The second technique shown uses a 45° metal mirror to accomplish the coupling and re-direct the light into the PWC layer. The third technique shown uses a curved waveguide to redirect the light from the collecting/concentrating cone into the PWC layer, e.g., coupling with a 90° waveguide bend.

As indicated above, a dielectric mirror reflects the solar radiation from the waveguide extension based on total internal reflection (TIR). In principle, this reflection could approach 100% for a smooth planar dielectric mirror surface. However depending on the collector/concentrator design, the angle of incidence (the angle between the normal to the mirror surface and the incident ray) of some of the rays exiting from the waveguide extension may be less than the critical angle needed for TIR and coupling into the PWC layer. In such cases ray leakage and light loss can result. This leakage and light loss can be significantly reduced using a metal coated mirror. Reflectivity of certain metals such as aluminum, silver, and gold over the solar spectrum can be very high, approaching 98% [Optics, E. Hecht and A. Zajac, Addison-Wesley Publishing Company, Reading, Mass., 4^{th} edition, 1974, p. 88]. As illustrated, another approach to couple the solar radiation into the PWC is a waveguide bend, typically a 90° waveguide bend. Such a bend can be shaped to have essentially 100% transmission through it [see, e.g., No-loss bent light pipe with an equiangular spiral, Shu-Chun Chu and Jyh-Long Chern, OPTICS LETTERS, Vol. 30, No. 22, Nov. 15, 2005]. Therefore it is possible to divert the solar radiation into the PWC with minimal loss using such a bend structure.

Once the light is in PWC, it is manipulated further to improve or adjust the level of concentration (that is, the light intensity), to do spectral separation if desired, and to divert it to the solar cell underneath. All these are accomplished using established guided wave techniques. Light is trapped into a multi-mode waveguide, and guided and manipulated along this waveguide. Single or multiple waveguide layers can be used for the PWC layer.

FIG. 46 shows the top schematic plan view of a PWC that uses a single waveguide layer. In this case the waveguide core is a low loss dielectric such as PMMA that can handle large optical powers [see e.g., Optical transmission of bulk plastic material and plastic lightguides at high optical powers, H. Reidenbach, F. Bodem, OPTICS AND LASER TECHNOLOGY, June 1975, p. 131]. In this example, the cladding is air, but in principle it could be any other lower index dielectric.

Light couples from the collecting/concentrating cones into the PWC as described above. Coupling takes place in the lightly shaded rectangular areas labeled as “exit aperture of the cone/collector and coupling element into PWC”. In this implementation light is focused into an optical waveguide using a taper, in effect an in-plane concentrator. The light in this waveguide is combined with the light already in another waveguide containing the already collected and combined light from the previous cones. In this case the combining is done using a Y-branch. Waveguide containing the previously collected light is bent using an S-curve or a Y-branch bend. In this implementation the taper, Y-branch and the S-curve bend form a basic unit that can be cascaded several times until the desired degree of combining and concentration is achieved.

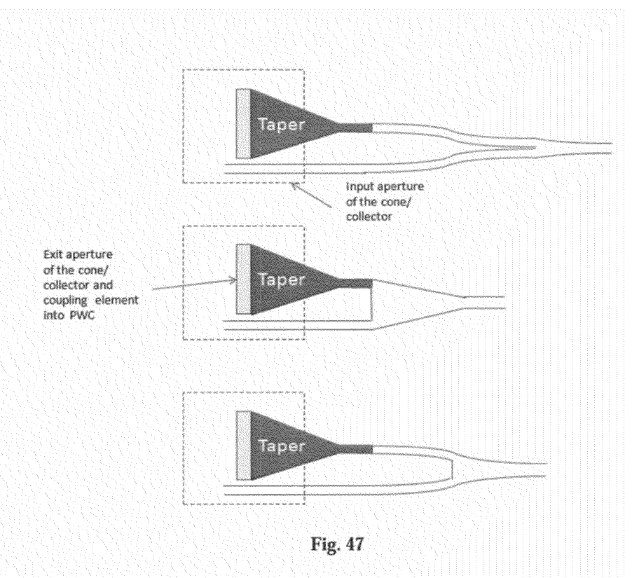

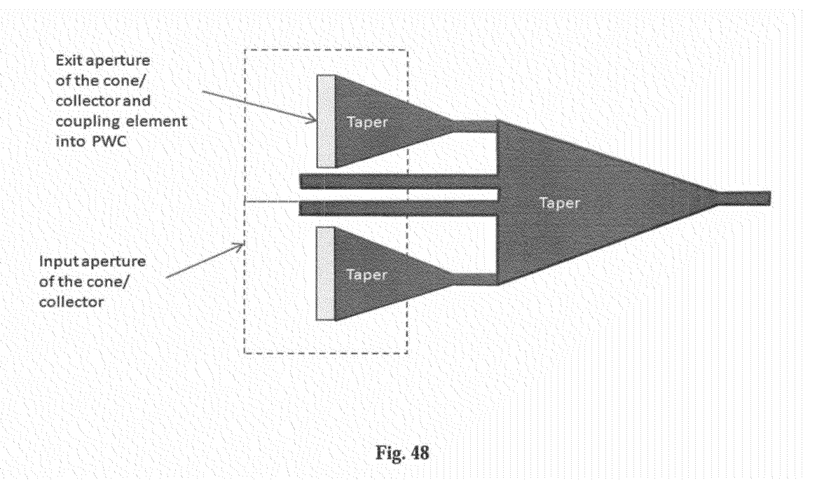

The combining and concentration can be done using other waveguide geometries and components or basic units. Some of these other basic unit possibilities are shown in FIG. 47. In all these units, horizontal output of the collecting cones is connected to a straight waveguide with a horizontal taper. In the top design the straight waveguide is connected to an S-bend which in turn is connected to a Y-branch combiner. Such S-bends may be smoothly curved or may have angles so long as TIR is maintained. In the middle design, the output of a cone and the waveguide that brings the light from a previous set of cones are fed into another horizontal taper. Both waveguides that feed into this horizontal taper also be connected with S-bends as shown in the bottom design. Other well known waveguide combiners can also be used. The width of the output waveguide can also be increased to improve collection efficiency. Furthermore, multiple waveguides can be combined using similar sub-structures. A particular exemplary implementation showing multiple waveguide combining is shown in FIG. 48. As shown in this example, in-plane taper concentrators for two adjacent collectors feed into another taper concentrator along with waveguides leading from collectors in another row of the collector array. A single waveguide then conducts the light from the multiple (in this case at least 4) collectors.

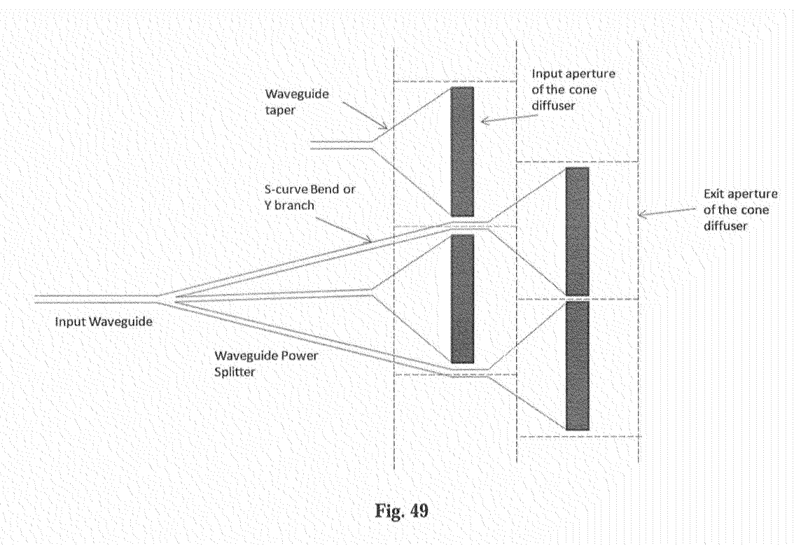

Such combining can be done a number of times until the desired level of concentration is obtained. If the size of the basic units shown in FIG. 47 and FIG. 48 is the same or less than the input aperture of the collecting cones, one layer of PWC is sufficient (although multiple layers could be used). After that the waveguide combining the desired level of light can transport the light to a point over the solar cell for illuminating part of the cell. Beneficially, this illumination is achieved by using an expanding taper to first spread the light. Then light is coupled to a down facing cone (functioning as a diffuser or light spreader) as shown in FIG. 49 using a coupling element, e.g., one of the coupling elements shown in FIG. 45.

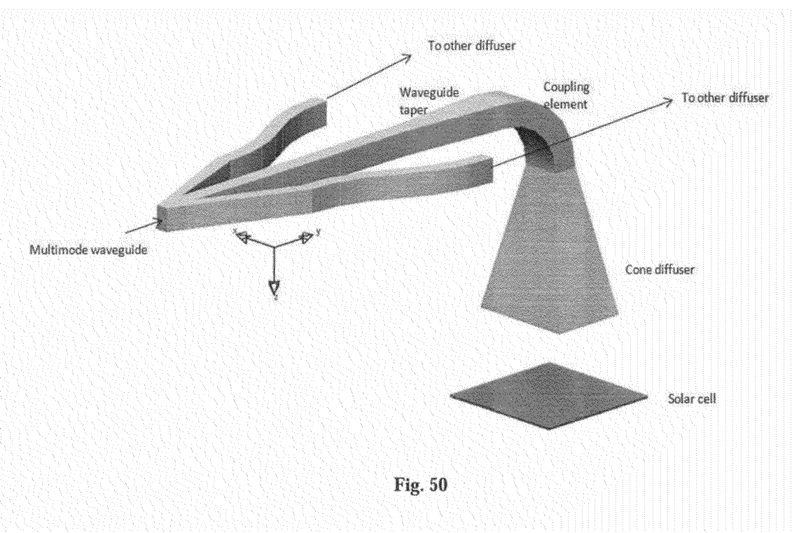

If the level of light concentration is too high for a single element diffuser, a power splitter can be used before the taper and cone diffuser to split the power into two or more waveguides. FIG. 50 shows the top schematic of such an arrangement in which the power in the incoming waveguide is first split into several waveguides using well known power splitters. Then the power in each waveguide is directed onto the solar cell underneath using an arrangement shown in FIG. 49.

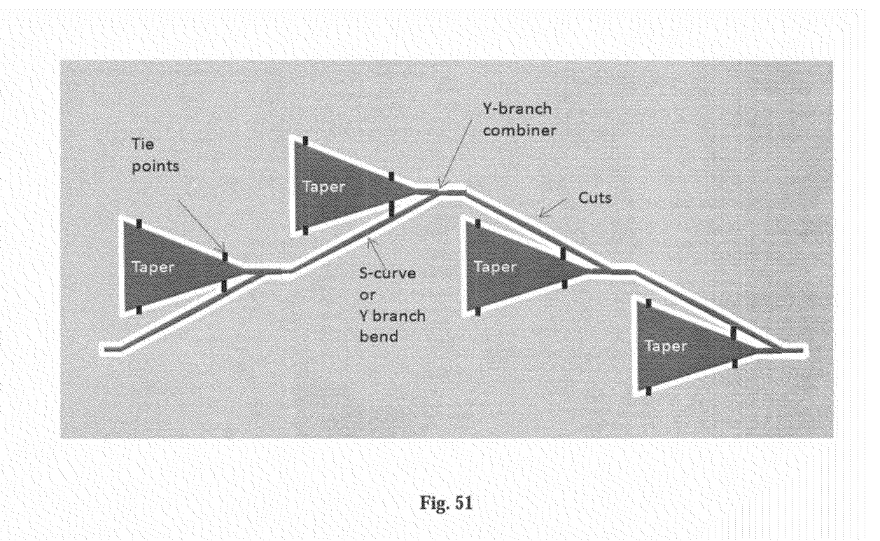

If the size of the basic units, e.g., as shown in FIGS. 46, 47 and FIG. 48, is the same or smaller than the input aperture of the collecting cones, one layer of PWC is sufficient. If low loss combining requires longer basic units, multiple layers (i.e., two or more) of PWC are needed. One layer of a PWC in a multi-layer implementation is shown in FIG. 51. In this case the size of the basic unit used for power combining is larger than the size of the input aperture of a collecting cone. Hence it is not possible to bring the outputs of the collecting cones into a single plane. The output of the cones that cannot be brought to the first PWC plane can be extended through this plane with a vertical waveguide and coupled into another PWC plane as shown in FIG. 41-43.

FIG. 42 shows two PWC planes connected to different sets of cones. Outputs of some of the cones are connected to the lower plane using a vertical waveguide extender. This extender goes through the first PWC plane. Different PWC planes are held together, in this case using spacers on areas that do not carry light. Using this approach multiple PWC layers can be stacked up. In this example, the basic unit used is shorter than the width of the two cones. Hence only two PWC layers are needed.

It should be noted that there is no need to shape a PWC layer such that only the waveguides, tapers, S-bends, etc. is left behind (i.e., only those light carrying elements are present in a layer). In other words there is no need to leave only the light carrying parts. One can, for example, start with a solid sheet of material and carve out thin cuts bounding the tapers, waveguides, and other elements to form the air claddings of the waveguides and waveguide elements as shown in FIG. 51. White areas are the cuts and the PWC is inside the cuts. This leaves most of the plane intact. Of course waveguides and waveguide elements should be connected to the rest of the plane at tie points to provide positional stability. It is possible to pick these tie points such that their presence do not significantly affect the light propagation. Examples of such tie points (as lateral ties and as vertical spacers) are shown in FIG. 42 and FIG. 43 and FIG. 51. In FIG. 51 a particular basic unit is used to illustrate the idea but does not limit the possible layouts.

This approach leaves substantial area in the PWC plane that does not carry light. Such areas in two different planes can be used to connect two different PWC planes with spacers.

To summarize this type of design, light collected by collector-concentrators (preferably in a close-packed array) is directed via mirrors or other coupling structure to waveguides within a layer. The waveguides are relatively narrow compared to the width of the collectors, and can be made even narrower by using tapers or in-plane concentrators. The waveguides need not be straight, but rather can be angles and/or curved to provide an uninterrupted path and/or to allow for the placement of other elements, such as waveguide combiners, spectrum separators, waveguide combiners, and light spreaders. In most cases, S-bend elements will be included to fit the waveguides to the geometric constraints. In particularly advantageous designs, air cladding (e.g., provided by narrow cuts adjacent to the various optical elements) can be used to provide the index of refraction difference needed for effective TIR. Similarly, air gaps can be provided between layers for the same purpose; spacers to maintain the gaps properly can be included, highly preferably in non-light conducting portions of the layers.

### Embodiment 2

### Planar Waveguide Circuit with One-to-One Mapping of Collection Area to Output Area

In a basic example of another design, a collector-concentrator, having rows and columns of micro-concentrators with a relatively thin profile (e.g. 5 mm in height) serves as a low value collector and concentrator of insolate light. Additionally, the collected light is coupled to a waveguide circuit, e.g., through micro-mirrors oriented at 45 degrees (from the plane of light's path) from the downward direction of the light at the bottom of the Collector-Concentrator, diverting the light by 90 degrees from its original path and directing it laterally within the waveguide layer.

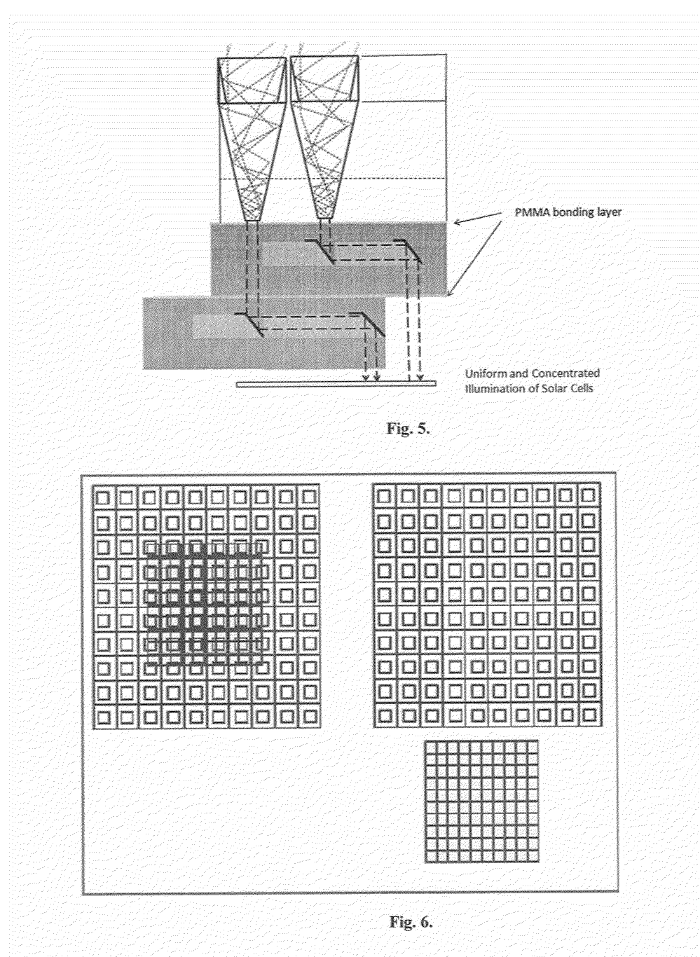

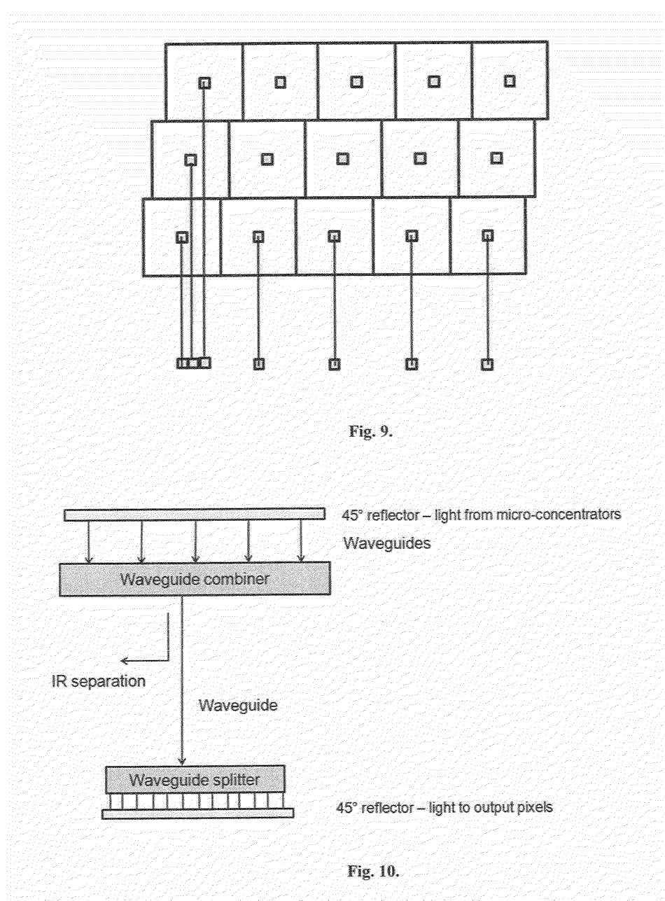

The path of the concentrated light, then parallel to the insolate surface of the concentrator, is in many cases transferred to an output aperture, again by a micro-mirror oriented at 45 degrees, by diverting it another 90 degrees to the downward direction where a solar cell device may be placed. Alternatively, the output aperture may be located at a lateral edge of the waveguide layer; in this case, the second mirror is not necessary. The concept of re-directing insolate radiation is illustrated in FIGS. 5-9.

### Embodiment 3

### Planar Waveguide Circuit: Arbitrary Spatial Correspondence Mapping of Collection Area to Output Area

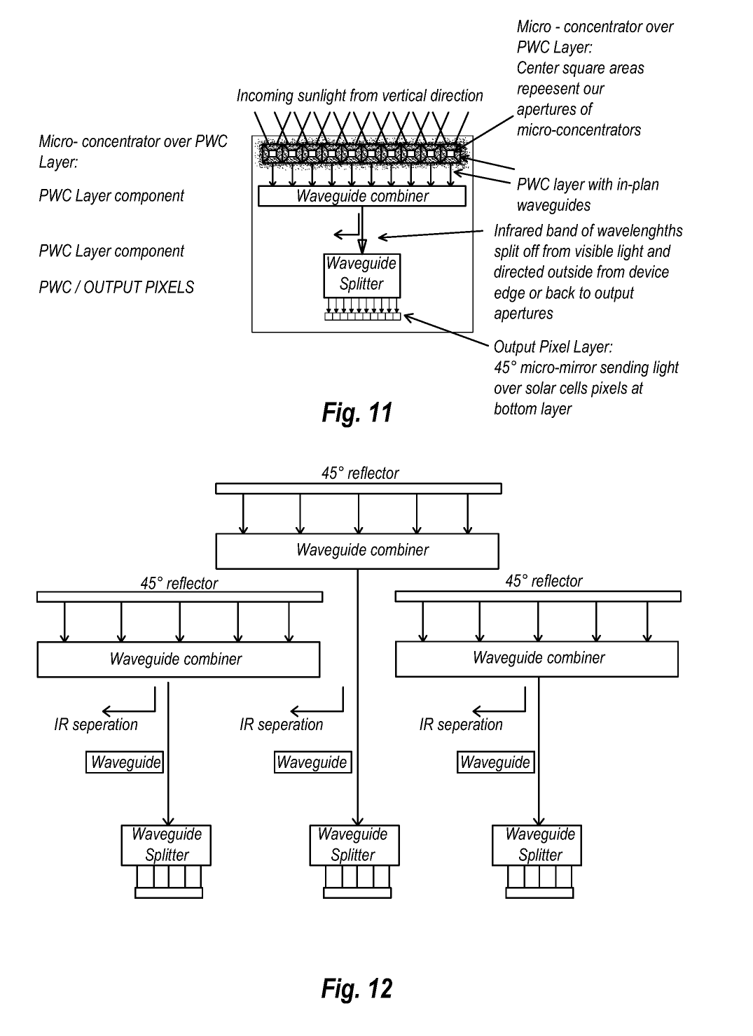

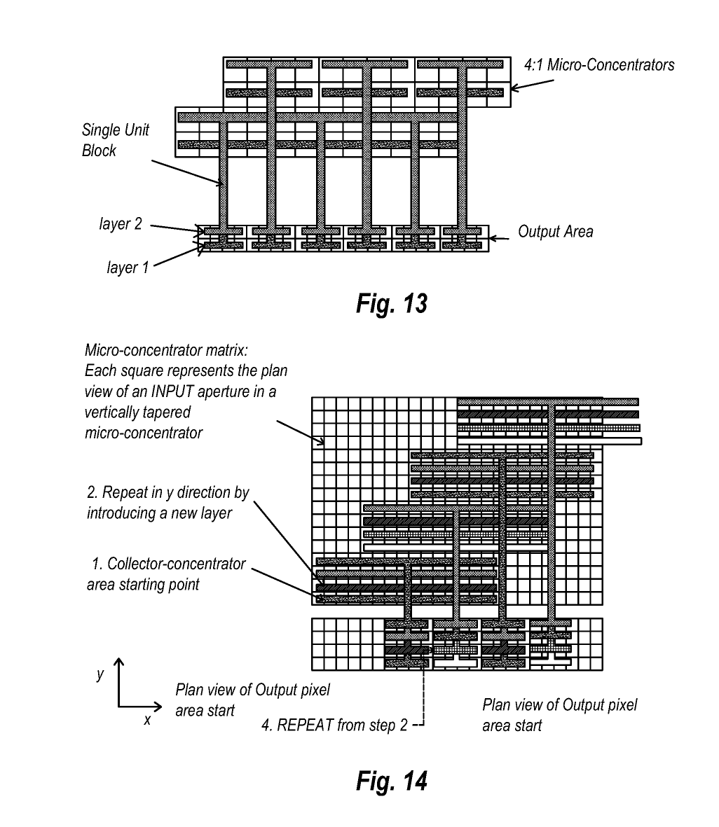

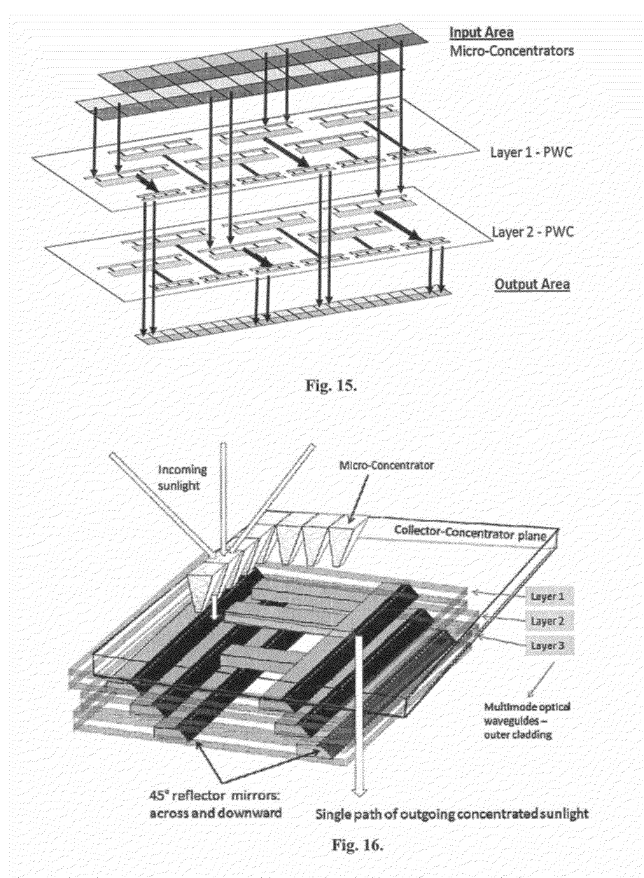

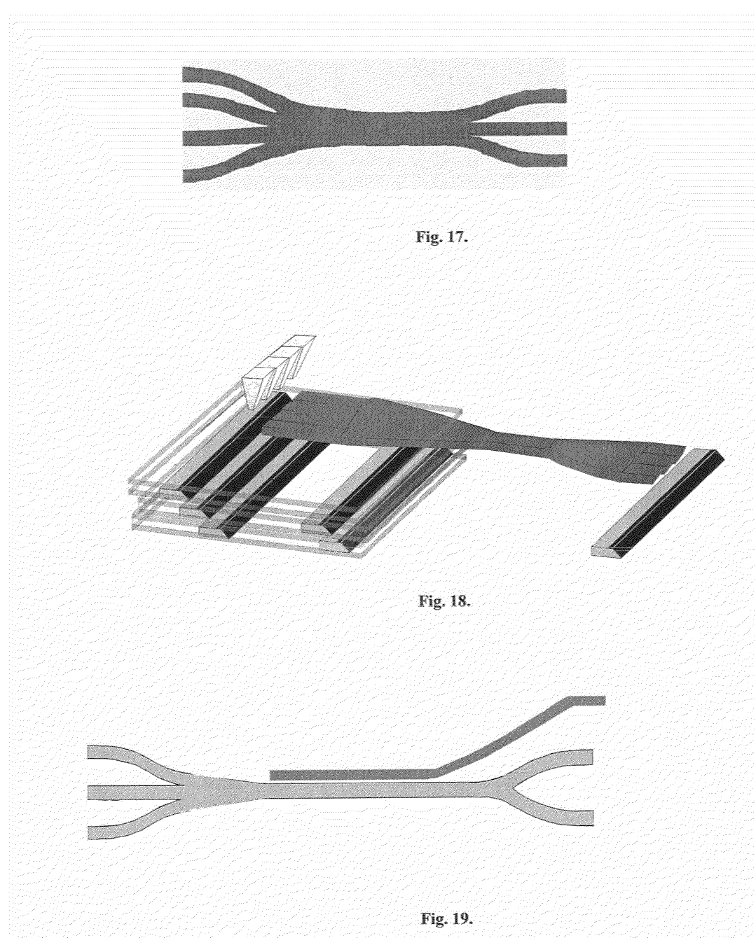

In designs similar to those illustrated in Embodiment 2, in order to arbitrarily map an area of light collection to an area of concentrated light, and to arbitrarily increase the concentration ratio, and use as few waveguide layers as possible, the basic PWC can be enhanced with additional optical circuit elements. As shown in FIG. 10-18, the light from an array of micro-concentrators can be coupled to a multimode combiner where a single waveguide is used to transport the combined light energy to output area, where a multimode splitter distributes the light to any number of output pixels.

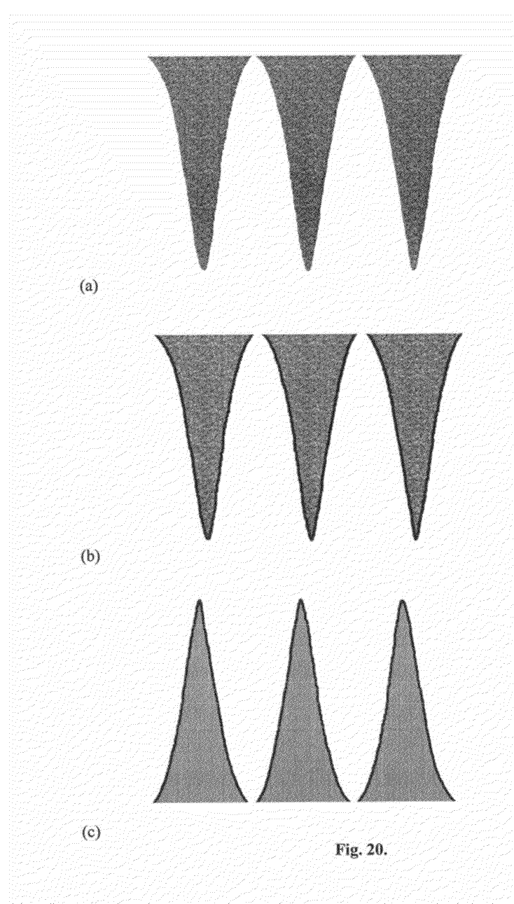

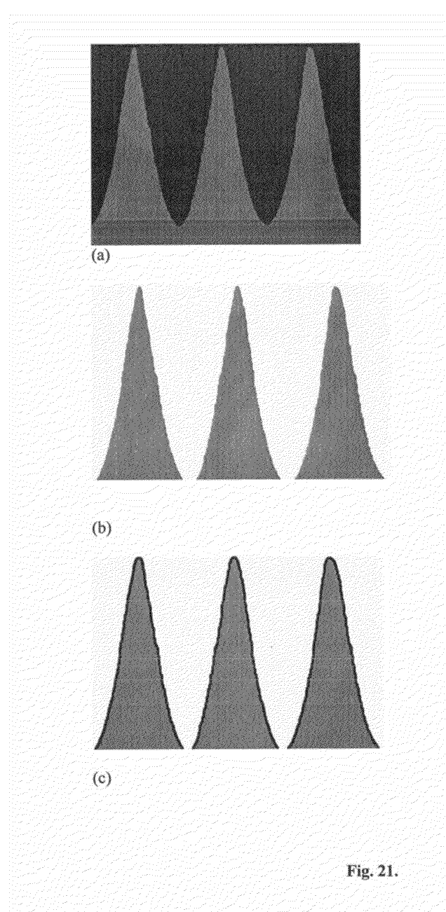

Optionally in the PWC, a wavelength separator may be introduced to split off infrared light to reduce solar cell temperatures, as shown in FIG. 19. Two methods of making an I R separator include routing back to a micro-concentrator, or partial micro-mirror to reflect downward and out to side, in addition to the thin film interference filter described below.

Spectral filtering structures can be introduced that modify the spectrum of light which the output pixel area receives.

The Collector-Concentrator initially concentrates by a factor Cf, and the output of the Collector-Concentrator is ‘combined’ by a PWC (multi mode combiner) with M inputs, then split to N outputs ‘pixels’ by a splitter (an inverted combiner) for a given ‘unit’ PWC circuit on one layer. For a given layer, then, the concentration factor, C_{f}, of the Collector-Concentrator is modulated by the combiners/splitters such that the overall concentration for a ‘pixel’ is given by

Cp=Cf×M/N.

There is an additional factor, Ac/Ap, the ratio of the areas of the Collector-Concentrator output aperture and the output aperture at the ‘pixels’, which we have assumed here is unity.

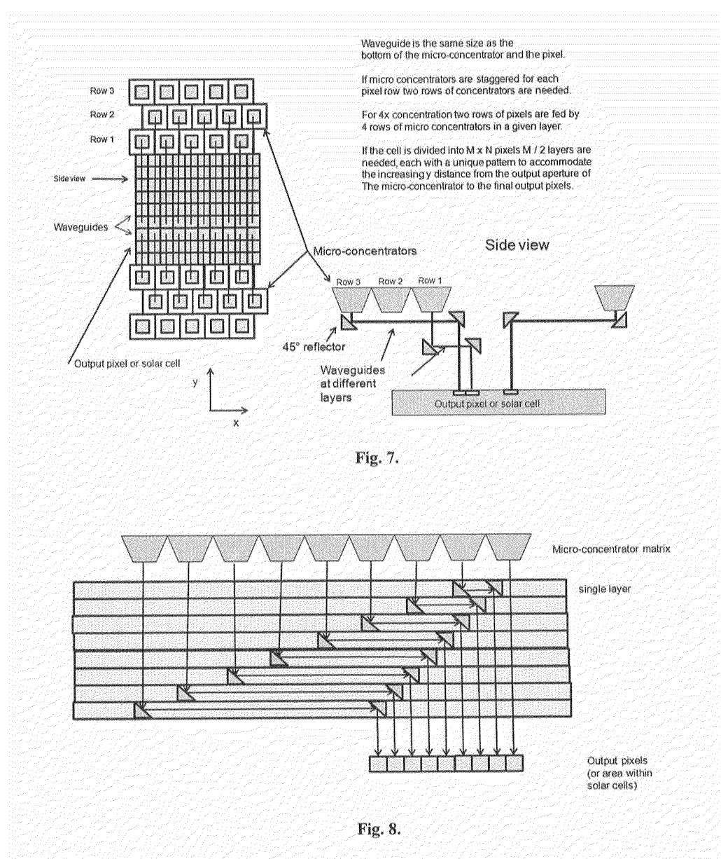

The interdigitated PWC array, with concentration Cp, can be repeated on additional upper levels (level 2 and above) by layering techniques, as shown in FIG. 7. Level 2 is connected to the next row of collectors, and so on, in an array of micro-collector concentrators, e.g., a square or hexagonal array of conical collectors. In advantageous embodiments, the micro-collector concentrator element can have domed input aperture surfaces to increase light collection and/or appropriately utilize graded refractive index (GRIN) material within the element volume. The output pixels receiving light from level two are shown on level two to simplify the drawing. All output pixels are understood to exist in the same plane, level 0 where a solar cell may be placed, and all levels channel light by vertical waveguides to level 0. The layers are registered over one another with lateral displacement for the collection of light for a given area, and so on, until preferably the entire output area is illuminated.

The design allows for ‘spatially-adjustable light concentration transformations’ through the combination of micro-concentrators coupled to multiplex light circuits and manifolds. That is, the array of micro-concentrators coupled to interdigitated PWCs allows for an arbitrary transformation of a planar area of light collection to another plane of illuminated area, where a solar cell may be attached. The intensity of illumination over the output pixel area can arbitrarily be made to vary spatially or be made to be uniform, and can be made to accommodate any type of solar cell.

### Design Example

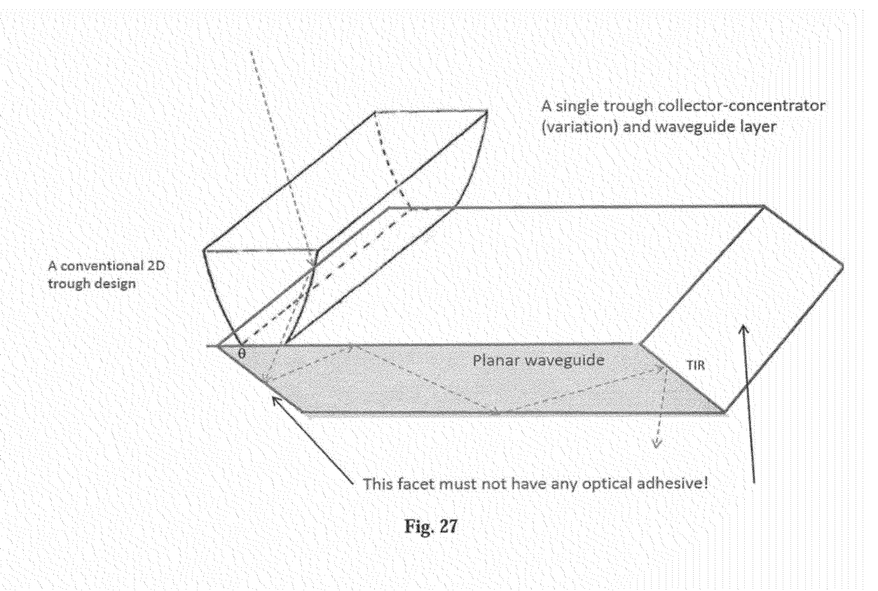

A design example focusing on the Planar Waveguide Circuit (along with some alternatives) is show in FIGS. 27-36. This design, and especially the PWC, is intended to direct the light by Total Internal Reflection (TIR). It should be recognized that the micro-mirror surface can be coated as previously described instead of using TIR. FIG. 27 schematically shows an exemplary trough-type collector (as an alternative to the collectors such as those illustrated in other figures herein) mounted above a waveguide layer such that output light from the collector is directed to the bevel micro-mirror and from the mirror through the waveguide layer to a second bevel micro-mirror which directs the light downward out of the waveguide layer.

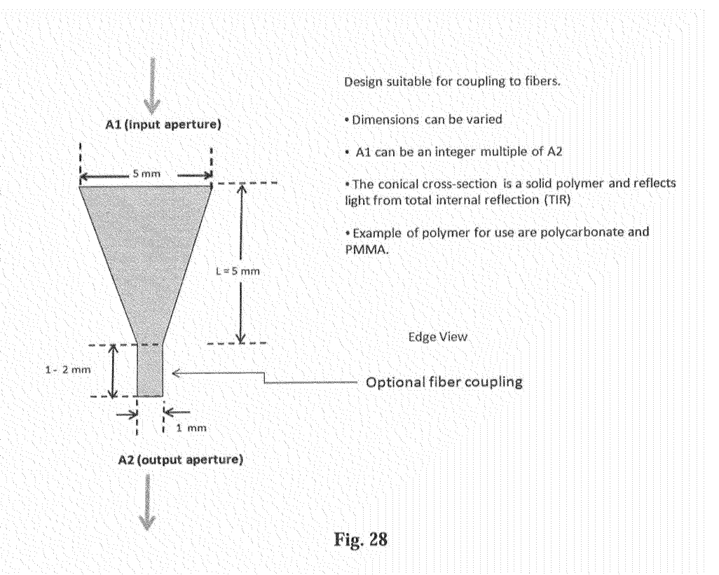

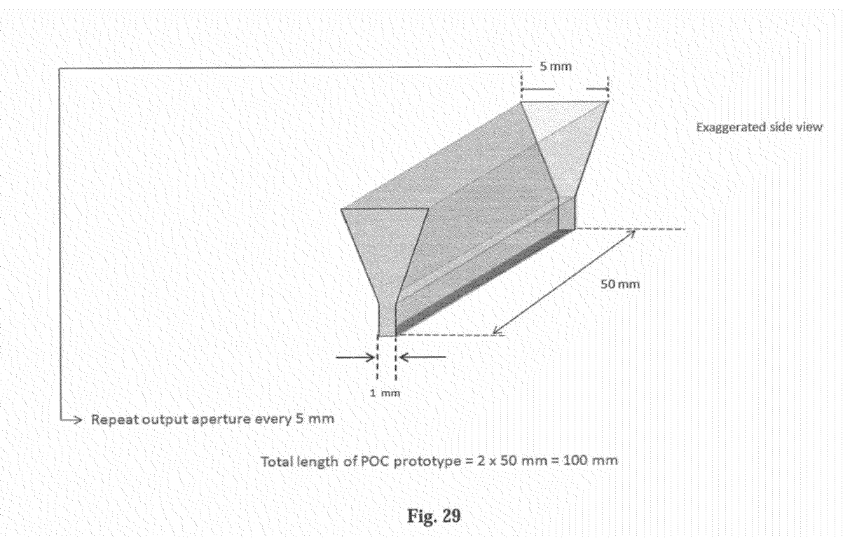

FIG. 28 schematically illustrates a conical collector with approximate dimensions. As indicated, this collector can be adapted for directing light to optical fibers or directly into a PWC. Similarly, FIG. 29 illustrates an embodiment of a trough-type collector with approximate dimensions.

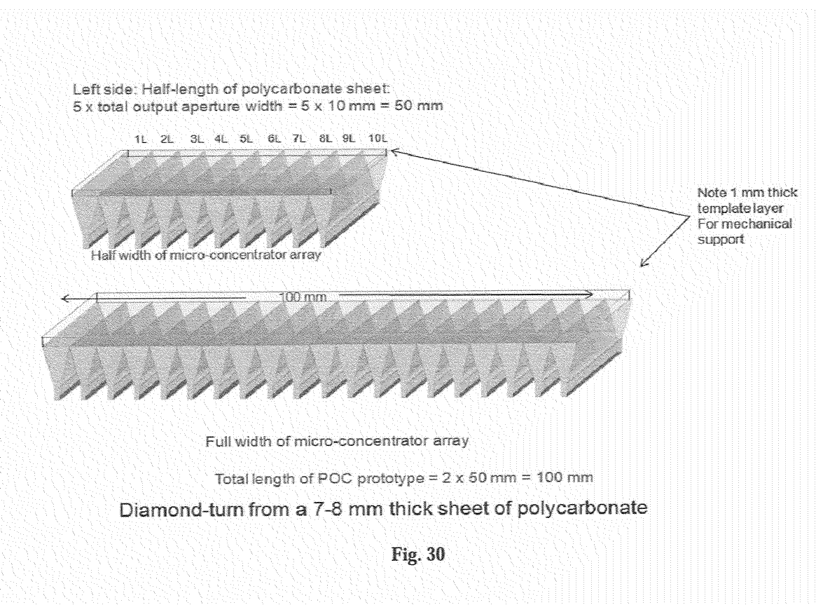

FIG. 30 illustrates an array of trough-type collectors as shown in FIG. 29. The collectors are aligned adjacent to each other with parallel long axes. In this case, the array is approximately 100 mm long, with 50 mm long left and right half arrays. Such an array can be formed in a number of different ways, including for example, by diamond-turning In this example, the collector troughs are formed in a sheet of polycarbonate (other materials may also be used) approximately 7-8 mm thick. As shown, a thin transparent sheet can be fixed to the top of the array, thereby providing mechanical strength.

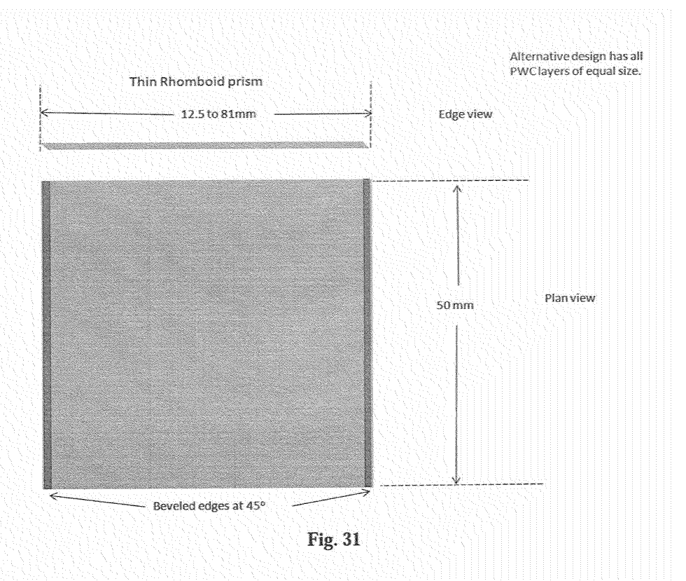

FIG. 31 illustrates a single PWC layer in edge and plan views, which is suitable for use with a collector array, e.g., an array as illustrated in FIG. 30. At each end of the PWC is a 45 degree bevel which functions as a micro-mirror to first direct light from the collector within and in the plane of the PWC, and then to direct the light out of the PWC substantially normal to the PWC plane, for example to a photocell.

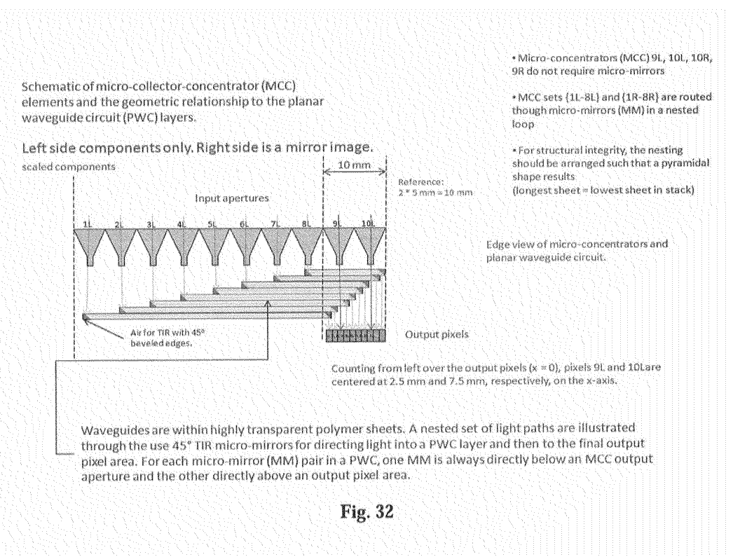

FIG. 32 shows a schematic cross-section through an assembly of a micro-collector concentrator array, a stacked PWC assembly, and an output pixel array. As illustrated, light enters the collectors and is transmitted down through the outlet apertures. From each collector, the light is directed to a 45 degree bevel micro-mirror where the light is reflected by TIR. In this design, air or other very low refractive index medium is in contact with the outer surface of the bevel. As an alternative, a reflective coating may be placed on the bevel. Light reflected from the micro-mirror is directed within a PWC layer generally in the plane of the layer. The PWC layer acts as a light channel, with TIR occurring as light reaches the upper or lower surface of the PWC layer. The PWC layers are stacked such that a micro-mirror receives the output from each of the collector array rows. Thus, the bevels receiving light from the micro-collector concentrators are stepped, with the distance of each step matching the spacing of the micro-collector concentrator outlet apertures. After passing through the PWC, light reaches a second bevel micro-mirror, where it is redirected downward out of the PWC as part of an output pixel array. The horizontal spacing between successive second bevel mirrors is the design spacing for the output pixel array, and will typically be less than the spacing for the first micro-mirrors. In this exemplary design, light output from the last two micro-collector concentrator array rows is not reflected within PWC layers, but instead is transmitted through the PWC layers to designed locations within the output pixel array. Of course, the assembly could be designed with all micro-collector concentrator outputs being directed to micro-mirrors and transmitted in-plane through PWC layers, or the assembly may be designed with 1, 2, 3, 4, or even more micro-collector concentrator row outputs being transmitted directly downward as part of the output pixel array.

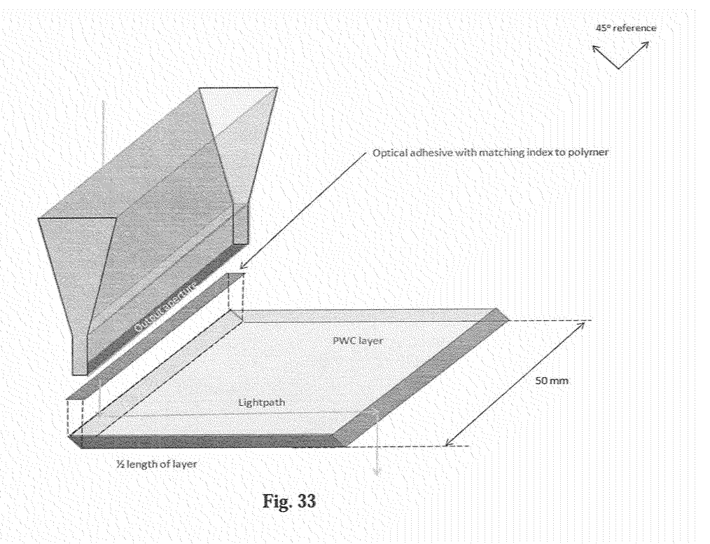

FIG. 33 is similar to FIG. 27, but emphasizes the optical coupling of the micro-collector concentrator to the top surface of the PWC. In this case an optically clear adhesive, preferably with similar refractive index to the PWC, is used.

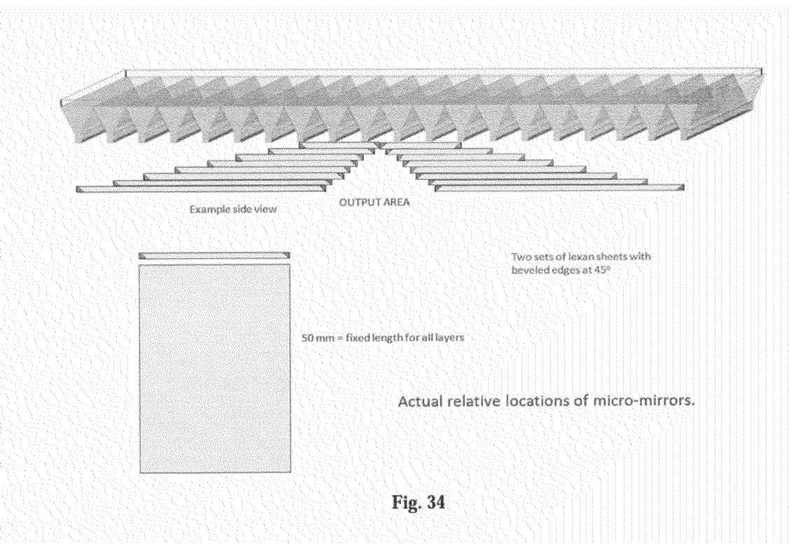

FIG. 34 schematically illustrates an assembly of micro-collector concentrators with corresponding PWCs, except showing both halves of a mirror-image assembly with central light output area. That is, light is collected from the left and right halves of the collector array, and directed toward the center, where the light from each PWC layer is redirected downwardly in the output area. In this example, the micro-collector concentrator array has a top or cover layer which protects and/or gives additional mechanical strength to the array. Also show is a single PWC layer in cross-sectional and plan views.

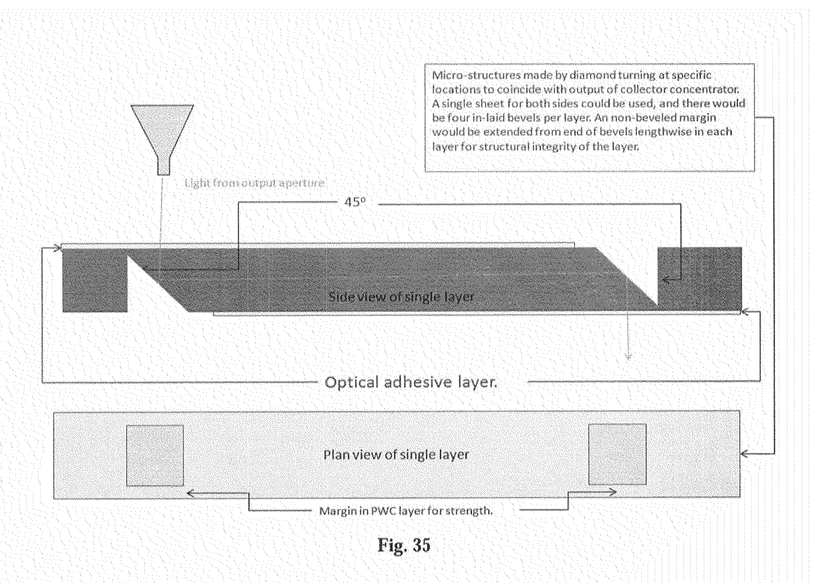

FIG. 35 schematically illustrates an alternative construction. In prior figures, the bevel micro-mirrors were formed at the edges of the PWC. In this case, the bevel micro-mirrors are formed within the sheet forming the PWC layer, e.g., by diamond-milling a bevel into the surface. The micro-mirror bevel can, for example, penetrate most but not all the way through the sheet and/or can extend laterally most but not all the way to the edges of the sheet. Leaving some material retains the remaining portion of the sheet in appropriate position. Light from a micro-collector concentrator will generally follow a path through the PWC as illustrated.

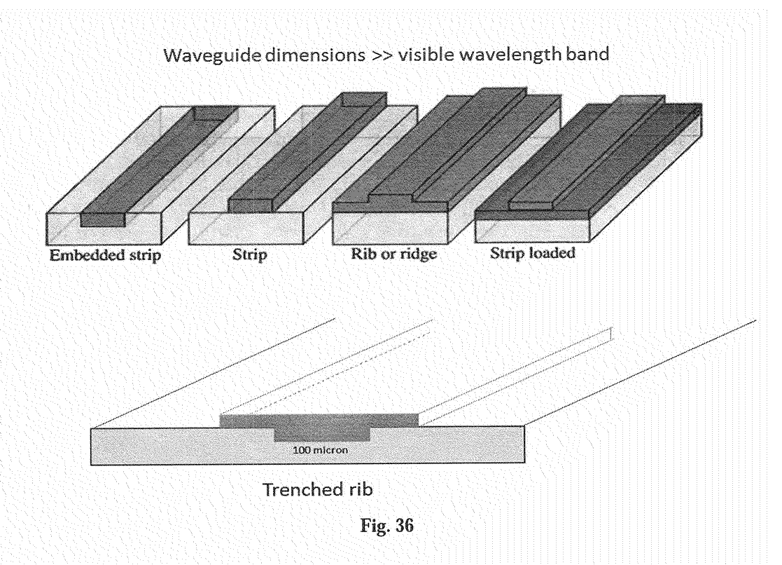

FIG. 36 schematically illustrates several contours of waveguides useful in the invention.

### C. Wavelength Separation

As pointed out above, in some cases it will be desirable to incorporate wavelength separation in the device, e.g., to separate infrared (IR) and/or ultraviolet (UV) wavelengths. Such separation can, for example be beneficial to reduce heating of the solar cells and/or to reduce UV-induced damage to materials. A useful approach wavelength separation is described below as applied to IR wavelength separation.

The IR part of the solar spectrum is not absorbed by silicon and other inorganic solar absorbers and, as a result, IR does not contribute to the electrical output of the solar cell. However, its presence results in heating the surrounding materials and solar cell and reduces efficiency of the solar cell. Therefore separating IR and diverting it away from the solar cell increases the efficiency. This can be done using wavelength selective reflective surfaces once the solar radiation is in the PWC. Such surfaces can be constructed out of thin film interference filter elements that are attached to part of the PWC before concentrated solar radiation is diverted to the solar cell.

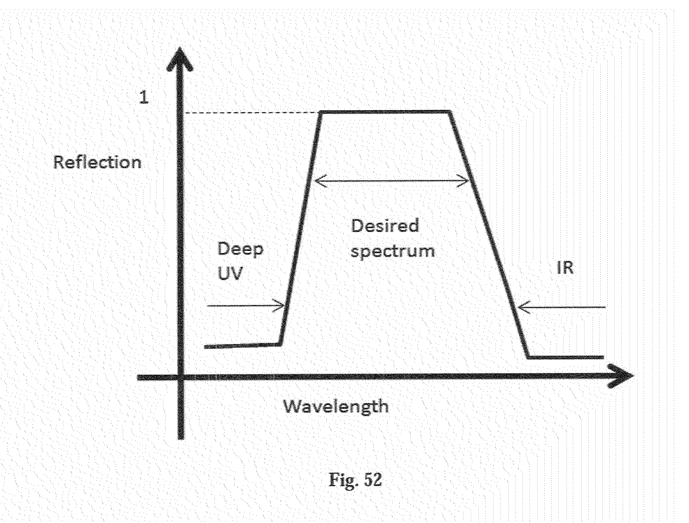

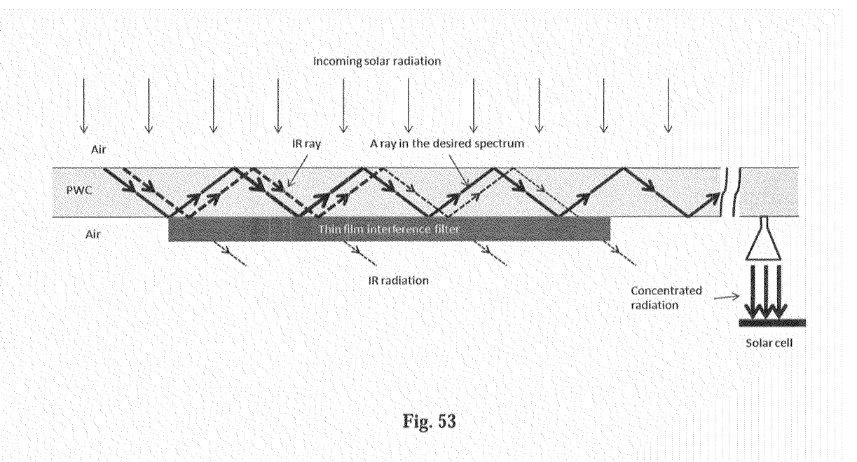

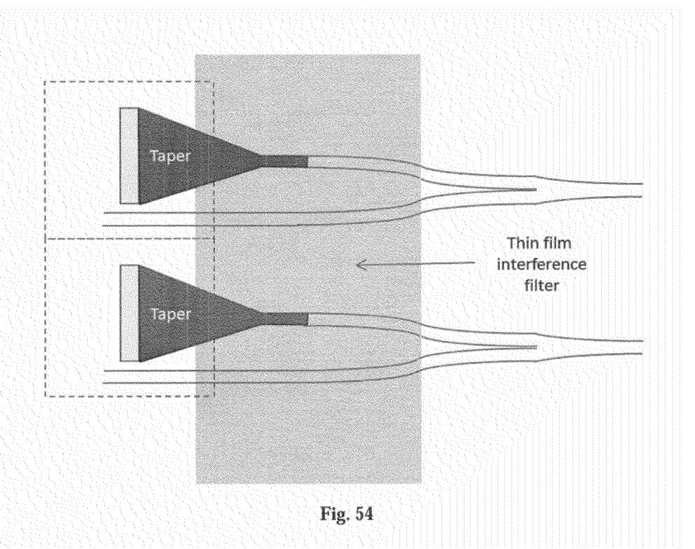

FIG. 52-FIG. 54 show a particular implementation of this idea. FIG. 53 shows a schematic view of the PWC showing a lateral location of the wavelength 30 selective surface made out of a thin film interference filter is attached. FIG. 54 is a schematic cross-sectional side view of a portion of the PWC waveguide with the thin film interference filter bonded to the bottom of the PCW layer. Of course, other locations along the waveguide could be used for locating the filter, including locations on the top of the PWC layer. Desired reflection spectrum of the wavelength selective surface is also shown in FIG. 52. As shown, a section of a thin film interference filter is bonded to (e.g., glued with index matched epoxy) to the PWC layer, here to the lower surface of the PWC layer. The thin film interference filter is designed such that it reflects the desired part of the solar spectrum with very high reflectivity, whereas IR and possibly the deep UV part of the spectrum experiences very low reflectivity. The reflectivity of such filters can be very close to unity over the desired spectral band with proper design, while being very low in adjacent spectral bands. Furthermore such filters can be very thin, e.g., on the order of 10s of microns.

Over the length of the thin film interference filter, reflection at the waveguide/filter interface is due to filter reflection instead of total internal reflection. Therefore the desired part of the solar radiation in the PWC reflects very strongly at this interface and is kept in the waveguide. On the other hand the IR part transmits through the filter and is radiated out. Since the solar cell element is placed further away from the thin film interference filter area, IR radiation essentially completely misses the solar cell and IR separation is achieved. The thin film interference filter can be placed anywhere under the PWC and its length should be adjusted so that most of the IR is separated out.

By adjusting the reflection spectra of the thin film interference filter or by providing another filter section adapted for passing different wavelengths, the UV, especially the deep UV) part of the spectrum can also or alternatively be filtered out. This part of the spectrum is not usefully absorbed by silicon either and causes efficiency reduction due to heating and potentially due to UV degradation of some system components.

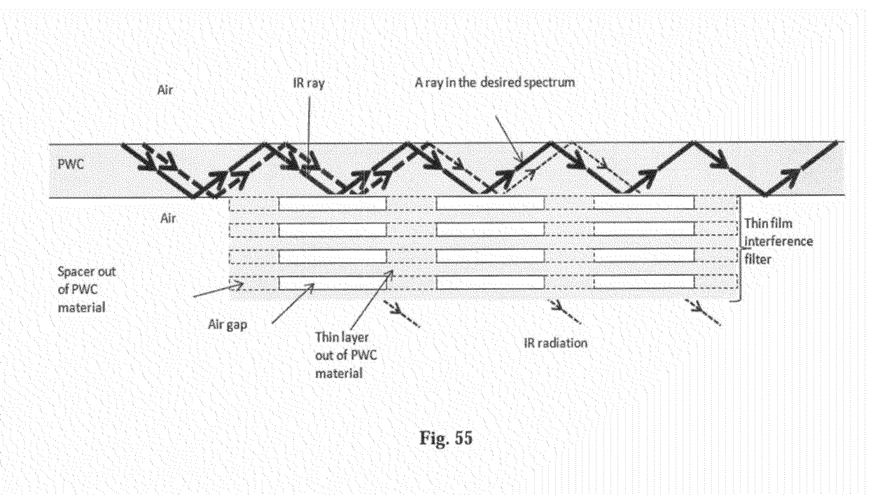

The thin film interference filter can also be fabricated during the fabrication of the PWC. The required multi-layer dielectric stack can be made out of air and PWC material. This provides a very high index contrast stack and the number of required layers can be significantly reduced. One approach to established and maintain the proper spacing of the stack layers is to use spacers of appropriate thickness separating layers of appropriate thickness made out of the PWC material as shown in FIG. 55.

Thus, FIG. 55 shows a cross-sectional profile of the thin film interference filter implementation made out of the PWC material and air. Spacers made out of the PWC material create thin air gaps that act as the low index dielectric. This figure shows many short sections of such stacks repeated along the PWC. This provides more mechanical integrity while performing the desired filtering function. Note that in order to make the filter construction clear this figure is not to scale. The thickness of thin film interference film is greatly exaggerated, as it would generally be much thinner than the PWC. Similarly, the width of the spacers is also relatively exaggerated and the distances between spacers in a particular layer is shown reduced from the spacing which would usually be used. In practice, usually the spacers would be as thin as practical while providing separation between the PWC layers (i.e., preventing unintended contact between PWC layers).

### D. Fabrication Methods for Exemplary Individual Optical Components

The various optical components may be fabricated and assembled in a number of different ways, commonly using readily available fabrication techniques. Examples of methods and materials for making the present devices are described below, but those materials and methods should not be regarded as exclusive or limiting. However, for fabrication ease and cost considerations, it is preferred that primarily polymeric materials are used in the fabrication of the entire flat solar concentrator.
1. Fabrication of Collector-Concentrators

As indicated above, the micro-collectors (collector-concentrators) can be constructed in various configurations. For example, useful individual micro-collectors may be formed in a range of different shapes and sizes, and may utilize reflective coatings or refractive index differences for guiding light from the collector input aperture to output aperture. The fabrication of the collector-concentrator layer can be accomplished using any of a number of different fabrication techniques. Suitable fabrication techniques for forming micro-features as in the present invention can, for example, include injection molding, hot embossing, etching, and the like.

Injection Molding

One advantageous method of fabricating collector-concentrators is using injection molding and is illustrated in FIG. 20. For example, in FIG. 20 panel (a), a polymer of a relatively low index, such as native poly(methyl methacrylate) PMMA, is injected into a mold that directs the polymer to the volume not occupied by the micro-concentrators (dark portions). It is also possible to fabricate the Collector-Concentrator matrix using the inverted injection process, i.e., fill in the micro-concentrator portion, the volume occupied by the polymer will provide more rigidity with this injection process. In FIG. 20 panel (b), a reflective surface such as a metallic thin film can be deposited on the vertical surfaces of the micro-concentrators. For example, a reflective coating such as AI or Ag deposited by vacuum deposition can be used to make a mirrored surface, as indicated in black. In FIG. 20 panel (c), the structure is shown in an orientation where incident light (typically sunlight) coming from above the top surface would be collected and would exit at the output apertures at the bottom.

As an alternative to a metallic mirror, a polymer of a higher refractive index than the body of the Collector-Concentrator can be injected into the center of the micro-concentrators. This process would require a more complex fabrication process, with an advantage of directing light towards the center of the micro-concentrator prior to reaching the output aperture. A solid sheet at the top surface of the micro-concentrators array, which serves to provide mechanical rigidity, can be incorporated into the injection molding process or bonded separately using an optical adhesive.

Hot Embossing

Concentrators can also be formed using hot embossing when the dimensions are suitable. In the hot embossing process, a pattern in a master is transferred to a thermoplastic material. If the dimensions are relatively large (>100 μm), the master can be made with conventional machining. Smaller dimensions can be produced by other known methods, e.g., using nickel electroplated through patterned photoresist.

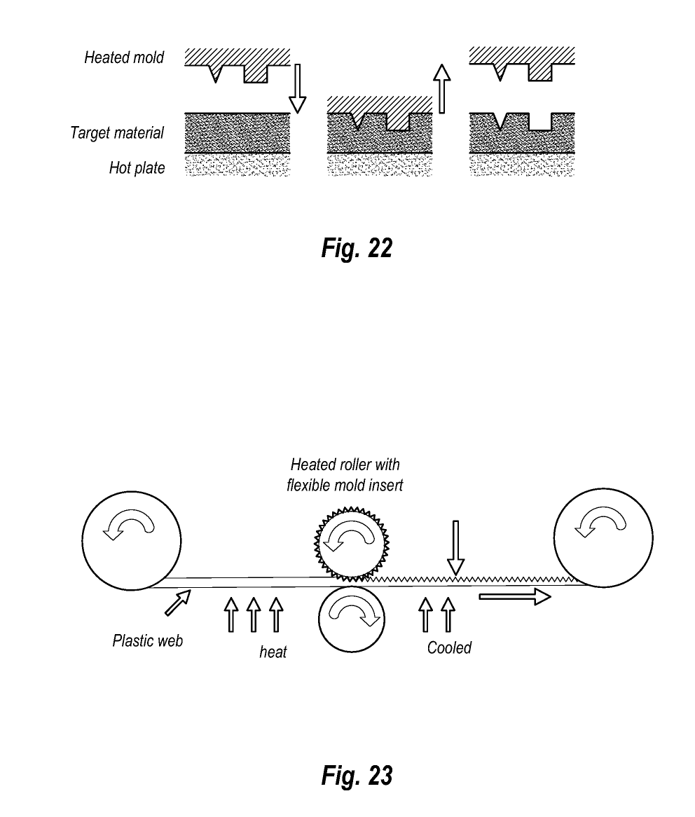

To perform the hot embossing, the master is pressed into the thermoplastic (e.g., PMMA, polycarbonate, polypropylene) just above the material's glass transition temperature. The master and plastic are cooled while in contact, are then separated, leaving a pattern in the plastic. This general process is illustrated in FIG. 22.

Hot embossing is used in micro-fluidics, for example, for creating trenches in substrates of thermoplastic. Several substrates can then be bonded together. Aspect ratios over 10 can be achieved, with the minimum feature size limited by the master.

Hot roller embossing of optical polymer sheets can also be used for the creation of microstructures. A polymer is selected that has a low index of refraction, such as native PMMA. After the hot-embossing process, the cavities formed for the light guides can be filled with a polymer of higher index, such as doped PMMA. A Collector-Concentrator is thus formed from the cavity in the polymer sheet, which not only has the proper geometric profile for the collection and concentration of sunlight, but also acts as a more efficient waveguide because of the filled interior. This structure seals the Collector-Concentrator array and efficiently directs light downward towards the output aperture. A schematic illustration of reel-to-reel hot embossing is shown in FIG. 23.

Dimensions of the mould master die can be replicated down to about 100 μm features within 2% tolerance, with greater than 85% of the mould depth embossed. Feature sizes down to 50 μm and feature depths up to 30 μm are achievable.

In FIG. 21, an example of a process of hot embossing for the fabrication of Collector-Concentrator is illustrated as follows. In FIG. 21 (a), the embossing master die, shown in the darkest color, forms the portion of the Collector-Concentrator that lies inside each of the micro-concentrators, i.e., the Collector-Concentrator cavity. The master deforms a sheet of suitable polymer (light gray portions) (e.g., reel-to-reel or by pressure deformation) under heated conditions such that the die penetrates through the polymer sheet to form the output apertures of the Collector Concentrator. (See the penetration of the master into the medium gray band at the bottom of FIG. 21(a).) The polymer sheet is cooled and the master released, leaving the Collector-Concentrator array as illustrated in FIG. 21(b). As illustrated in FIG. 21(c), the inner walls of the Collector-Concentrator cavities can be coated with a reflective coating, e.g., a metallic coating as mentioned above for Collector Concentrators formed by injection molding.

The Collector-Concentrator can alternatively be fabricated by embossing in the opposite manner, in which the cavities are formed between micro-concentrators, leaving filled micro-concentrators with the polymer sheet material. The difference in this case is that the sheet is sealed and flexibility is greater, which could be desired if the final sealing process is reel-to-reellamination. The cavity between micro-concentrators is now comprised of air; hence the solid polymer micro-concentrators of a much higher index are waveguides to direct incoming light from the surface to the bottom output aperture.
3. Fabrication of PWC Layers

Waveguides may be formed using a number of different suitable materials. Persons familiar with this field can select appropriate waveguide materials.

Many polymers are commercially available which are suitable for fabrication of the optical elements. One requirement is that the optical density must be sufficiently low to avoid absorption losses in the optical path. Optical grade PMMA, CR-39, select Topas and Zeonex polymers are example of higher quality polymers.

PMMA can be produced with very low optical density (ReidenBach and Bodem), and therefore could be the material of choice in the polymer family. PMMA can be used for this invention if manufactured with sufficiently low optical density that is consistent for achieving acceptable optical efficiency

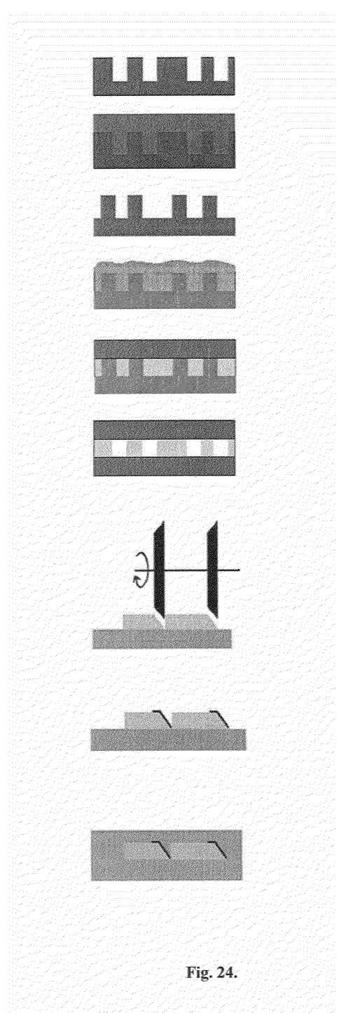

One way of forming waveguides from a material such as PMMA uses PDMS (polydimethylsiloxane). PDMS is a silicon elastomer which is flexible and deformable, and provides a method for making microstructures through casting. It is a common material used for fabricating waveguides. A suitable type of PDMS can be readily selected by those familiar with such casting methods. Thus, PDMS can be used to fabricate waveguides for the present invention, e.g., by the following process, which is illustrated schematically in FIG. 24:

Step 1: micro-structuring of master positive. Various materials can be used, e.g. diamond-like-carbon coated stainless steel.

Step 2: casting of PDMS negative onto structured master.

Step 3: curing of PDMS negative and release from positive and invert substrate.

Step 4: casting of PMMA with high refractive index onto the PDMS negative.

Step 5: pressing low refractive index liquid PMMA plate onto the liquid polymer using a weight; volatilize solvent.

Step 6: Release PDMS mold and invert substrate

Step 7: Diamond blade machining of beveled edges for 45° mirrors. For a given length of a waveguide in a design, multiple blades with a specific spacing can be used to define the waveguide ends to reduce process time.

Step 8: Aluminum or silver sputter metallization, photolithograhy patterning, and chemical wet etch back to fabricate mirrors on beveled surfaces.

Step 9: Coating of un-doped PMMA for cladding layer. Steps complete for planar waveguide

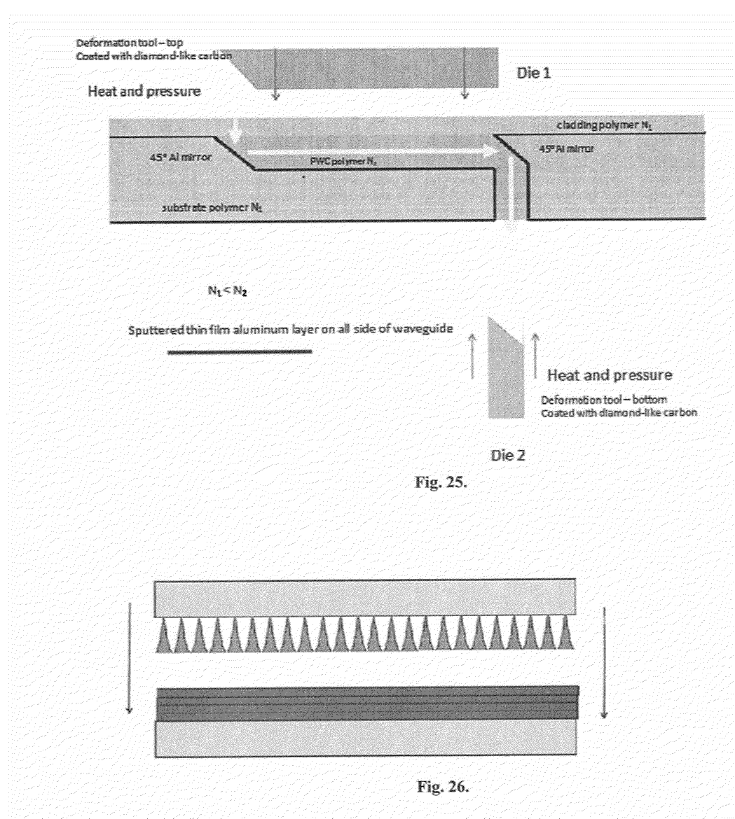

Another exemplary process is illustrated in FIG. 25. As illustrated, a waveguide volume is created in a substrate polymer sheet, e.g., using a deformation tool (i.e., a die) with heat and pressure. The substrate polymer has a refractive index N₁. The tool can create an angled surface at one end of the volume which will be a micro-mirror. A second deformation tool can be used to create a via hole and a second angled surface at the other end of the waveguide volume. A thin film of reflective material, e.g., aluminum, is coated onto the surface of the formed substrate, such as by sputtering. A polymer, referred to here as PWC polymer, having refractive index N₂ is used to fill the PWC volume. For the different polymers, N₁<N₂. A cladding layer can be added on top of the substrate/filled PWC volume assembly, also with refractive index<N₂. This polymer may be the same or different as the substrate polymer.

Of course, many other methods and variations can be used for constructing PWCs.
4. Bonding and Enclosure Layers

The construction of the micro-collector concentrator arrays and PWC layer assemblies can be carried out in a variety of ways.

For example, one option for the encapsulation process to make the final product of the invention, which is a flat and thin sheet of the integrated layers, includes a registration and bonding process of the layers. The Collector Concentrators are bonded to an upper sheet of thin glass or rigid polymer, while the PWC layers are bonded to a lower sheet of glass or rigid polymer. An optical grade epoxy can be spray deposited or otherwise placed at selected positions on either layer, then the layers are compressed and cured. Curing can be accomplished by UV light for example. Alignment can be accomplished by pattern recognition of fiducials in the layers during fabrication. Such a construct is illustrated in FIG. 26, with a top layer of glass or plastic, a layer of micro-collector concentrator array, multiple layers of PWC, and a bottom glass or plastic layer. When formed in this manner, the device provides a relatively rigid and strong unit with both the collectors and the PWCs protected.

### E. Definitions

As used in connection with this invention, the terms “insolate light”, insolate radiation“, “insolate energy”, and the like refer to sun exposure light, radiation, energy, etc., and thus involve incident sunlight.

As used herein, the term “photovoltaic” has its usual meaning, referring to the conversion of light, especially sunlight, into electrical energy, and includes both the process and devices and systems for such conversion.

In reference to micro-concentrator arrays and waveguides, the term “flat” as used herein means the indicated component or device is extended in two orthogonal dimensions (which can be considered as defining a plane) and relatively thin in the third dimension (i.e., the thickness is substantially less than either of the orthogonal plane dimensions. In many cases, such a component or device the thickness will be no more than 0.2, 0.1, 0.05, 0.02, or 0.01 times the less of the two planar dimensions.

In the context of this invention and in reference to light, the term “concentrate” and similar terms mean that incident light over an incidence area is manipulated such that it is transferred to an output area which is less than the incidence area, resulting in a higher average light intensity over the output area as compared to the incidence area.

As used herein, the term “micro-concentrator” refers to a small light concentrator, typically having a depth less than a few centimeters, and highly preferably less than 1.5, 1.2, 1.0, 0.7, or 0.5 cm or even less. In the context of such light collectors or collector-concentrators, the term “wide angle” refers to the full angle over which the majority of incident light on the light input aperture of the collector will be collected (and in the case of concentrators, also concentrated) being a wide angle, preferably at least 45, 50, 60, 65, 70, 80, 90, 100, or 120 degrees.

The term “collector-concentrator” as used herein refers to a light collector which is constructed such that light which enters the collector through its input aperture (i.e., inlet aperture) is concentrated to pass through an outlet aperture which is significantly smaller in cross-sectional area than the inlet aperture.

A “trough-type concentrator” or “trough concentrator” refers to a light concentrator which is generally trough-shaped, that is, the inlet aperture is generally rectangular (although it may have rounded corners) with a length at least 4, and usually at last 7 or 10 times the width. As described for concentrators herein the interior of the concentrator may be empty or may be filled with a material having a suitable refractive index, and/or the walls may be bare or coated, e.g., with reflective metal.

The term “in-plane concentrator” refers to a structure in a PWC layer or plane which concentrates inlet light. A common structure for such an in-plane concentrator is a taper, where the inlet aperture is the wide end of the taper and the outlet aperture is at the narrow end of the aperture. Conversely, a reverse taper or inverted taper may be used to spread light received from a waveguide or the like.

As used in connection with waveguides, the term “S-bend” refers to a shape which is bent or curved first in one direction and then bent or curved back toward the original direction, generally within the same plane. The shape can also be regarded as somewhat sigmoid.

In reference to waveguides, the terms “junction” and “combiner” refer to a structure in a PWC where two or more waveguides connect such that light from multiple inlet waveguides passes out through a common waveguide. An example is a Y-combiner.

Conversely, the term “splitter” refers to a structure in a PWC where two or more waveguides connect such that light from one or more inlet waveguides passes out through a number of waveguides which is greater than the number of inlet waveguides. In most cases, there will be one inlet waveguide and two or more outlet waveguides.

As used in connection with optical elements in the present devices, the term “cladding” refers to a material with is immediately adjacent to and forms a boundary with the reference structure. For example, “air cladding” refers to an air layer which is adjacent to a reference structure (e.g., in-plane concentrator, waveguide, junction, splitter, or other optical element in a PWC). In this case, the cladding material will have a lower refractive index than the material of the reference structure to which it is adjacent.

In the present context, indication that two components or devices are “optically connected” or “optically coupled” means there is a light path by which light is directed from one component to the other.

All patents and other references cited in the specification are indicative of the level of skill of those skilled in the art to which the invention pertains, and are incorporated by reference in their entireties, including any tables and figures, to the same extent as if each reference had been incorporated by reference in its entirety individually.

One skilled in the art would readily appreciate that the present invention is well adapted to obtain the ends and advantages mentioned, as well as those inherent therein. The methods, variances, and compositions described herein as presently representative of preferred embodiments are exemplary and are not intended as limitations on the scope of the invention. Changes therein and other uses will occur to those skilled in the art, which are encompassed within the spirit of the invention, are defined by the scope of the claims.

It will be readily apparent to one skilled in the art that varying substitutions and modifications may be made to the invention disclosed herein without departing from the scope and spirit of the invention. For example, variations can be made to the materials used and the dimensions of the parts. Thus, such additional embodiments are within the scope of the present invention and the following claims.

The invention illustratively described herein suitably may be practiced in the absence of any element or elements, limitation or limitations which is not specifically disclosed herein. Thus, for example, in each instance herein any of the terms “comprising”, “consisting essentially of” and “consisting of” may be replaced with either of the other two terms. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

In addition, where features or aspects of the invention are described in terms of Markush groups or other grouping of alternatives, those skilled in the art will recognize that the invention is also thereby described in terms of any individual member or subgroup of members of the Markush group or other group.

Also, unless indicated to the contrary, where various numerical values or value range endpoints are provided for embodiments, additional embodiments are described by taking any 2 different values as the endpoints of a range or by taking two different range endpoints from specified ranges as the endpoints of an additional range. Such ranges are also within the scope of the described invention. Further, specification of a numerical range including values greater than one includes specific description of each integer value within that range.

Thus, additional embodiments are within the scope of the invention and within the following claims.

What is claimed is:

1. A linked flat solar concentrator and photovoltaic device, comprising
a flat array of wide angle solar micro-concentrators mounted on and optically coupled with a waveguide layer; and
a flat photovoltaic panel, wherein said flat array and said flat photovoltaic panel are optically connected such that light concentrated by said solar concentrator is directed onto said photovoltaic panel thereby producing electricity.

2. The device of claim 1, wherein said flat array is mounted on top of said photovoltaic panel.

3. The device of claim 1, wherein said photovoltaic panel is mounted on an edge of said flat array.

4. The device of claim 1, wherein said waveguide layer comprises a first set of mirror surfaces which redirect light exiting said concentrators substantially in the plane of said waveguide layer.

5. The device of claim 4, wherein said waveguide layer comprises a second set of mirror surfaces which redirect light from said first set of mirror surfaces to a direction substantially perpendicular to the plane of said flat array.

6. The device of claim 1, wherein light from said concentrators is coupled to said waveguide layer through 90 degrees waveguide bends.

7. The device of claim 1, wherein said flat array concentrates insolate light by a factor of at least 2.

8. The device of claim 4, wherein a said wave guide layer comprises a pair of beveled edges of said waveguide layer.

9. The device of claim 1, wherein a said waveguide layer comprises at least angled mirror surface internal to said waveguide layer.

10. The device of claim 1, wherein said concentrators are trough-type collector concentrators.

11. The device of claim 1, wherein said concentrators are near square concentrators.

12. The device of claim 1, wherein said PWC comprises a single layer comprising a waveguide which includes at least one S-bend and at least one junction.

13. The device of claim 1, wherein said PWC comprises at least one layer, each said layer comprising a waveguide which includes at least one S-bend and at least one junction.

14. The device of claim 13, further comprising an in-plane concentrator.

15. The device of claim 13, wherein said waveguide has lateral air cladding.

16. The device of claim 15, wherein said waveguide has vertical air cladding.

17. The device of claim 13, wherein said PWC comprises a plurality of layers separated by air gap defined by spacers between said layers.

18. The device of claim 13, wherein said waveguide is optically coupled to a diffuser which spread light from said waveguide over the surface of a photovoltaic cell in said photovoltaic panel.

19. The device of claim 1, further comprising a wavelength separator which preferentially separates and removes light in a particular portion of the light spectrum from light which is conducted to said photovoltaic panel.

20. The device of claim 19, wherein said wavelength separator separates and removes infrared wavelengths.

21. The device of claim 19, wherein said wavelength separator comprises a thin film interference filter.

22. A flat solar concentrator, comprising a flat array of wide angle solar concentrators mounted on and optically coupled with a waveguide layer, wherein said waveguide layer is configured such that light exiting from said concentrators is redirected within said layer to a direction parallel to the plane of said layer and light emitted from said waveguide layer is emitted over an area substantially less than the area over which light is collected by said flat array of wide angle solar concentrators.

23. The solar concentrator of claim 22, wherein said light exits said layer substantially perpendicular to the plane of said layer.

24. A method for making a flat solar concentrator, comprising optically coupling a flat array of wide angle solar micro-concentrators having an incident light area with a waveguide layer, wherein said waveguide layer accepts output light from said concentrators and outputs light into a light output area smaller than said incident light area.

25. The method of claim 24, wherein said light output area is from about 0.5 to about 0.1 times the incident light area.

26. The method of claim 24, wherein said waveguide layer comprises a plurality of sub-layers.

27. The method of claim 24, wherein said flat array has a thickness of about 0.01 to 2.5 cm.

28. The method of claim 24, wherein said waveguide layer has a thickness of less than about 0.7 cm.

29. The method of claim 24, wherein said flat array is bonded with said waveguide layer.

30. A method for reducing the photovoltaic panel area required in a photovoltaic power system of a specified electrical power generation capacity, comprising including in said system a flat solar concentrator as specified in optically coupled with at least one photovoltaic panel in said system, wherein the flat solar concentrator is included in a flat array of wide angle solar micro-concentrators mounted on and optically coupled with a waveguide layer; and wherein said photovoltaic panel is a flat photovoltaic panel, wherein said flat array and said flat photovoltaic panel are optically connected such that light concentrated by said solar concentrator is directed onto said photovoltaic panel thereby producing electricity.
